(19) United States
(12) Patent Application Publication
(10) Pub. No.: US 2026/0308319 A1
(43) Pub. Date: Oct. 8, 2026

(54) FLUORINE-FREE FERROELECTRIC POLYMERS

(71) Applicant: CASE WESTERN RESERVE UNIVERSITY, Cleveland, OH (US)

(72) Inventors: Lei Zhu, Solon, OH (US); Jiahao Huang, north Royalton, OH (US); Nan Hin Kwok, Hong Kong (HK); Guanchun Rui, State College, PA (US)

(21) Appl. No.: 19/638,184

(22) Filed: Apr. 3, 2026

Related U.S. Application Data
(60) Provisional application No. 63/782,698, filed on Apr. 3, 2025.

(51) Int. Cl. C08G 65/334; H10K 85/10; H10N 30/857

(52) U.S. Cl. CPC C08G 65/3346; H10K 85/10; H10N 30/857; C08G 2250/00

(57) ABSTRACT

A fluorine-free ferroelectric polymer includes a main chain and sulfonylated alkyl side chains, wherein each sulfonylated alkyl side chain includes at least one sulfonyl dipole, and wherein a sulfonyl group of each sulfonylated alkyl side chain is linked to the main chain with an at least 3 atoms in length aliphatic or heteroaliphatic linker.

### RELATED APPLICATION

This application claims priority from U.S. Provisional Application No. 63/782,698, filed Apr. 3, 2025, the subject matter of which are incorporated herein by reference in its entirety.

### GOVERNMENT FUNDING

This invention was made with government support under 2103196 awarded by the National Science Foundation and DE-SC0018075 awarded by the Department of Energy. The government has certain rights in the invention.

### BACKGROUND

Ferroelectric (FE) materials feature direct cross-couplings between electric polarization and diverse other properties, enabling applications in sensors and actuators, electrocaloric cooling, capacitors, and energy harvesting. Compared to FE ceramics, polymer ferroelectrics offer several advantages, including good flexibility, easy fabrication into complex shapes, lower weight and cost, and better acoustic impedance matching biological tissues. Despite decades of research, however, only a limited number of FE polymers have been discovered; the most important are poly(vinylidene fluoride) (PVDF)-based fluoropolymers, hydrogen-bonded nylons, and liquid crystalline polymers (LCPs) with a chiral smectic C (SmC*) phase. Among these, only PVDF-based fluoropolymers have emerged as a successful FE polymer platform with a well-defined Curie transition and a large spontaneous polarization. However, manipulating the semicrystalline structures of FE fluoropolymers via chemical modifications to achieve tunable FE properties and high performance, such as transitioning from P(VDF-co-trifluoroethylene) [P(VDF-TrFE)]-based copolymers to terpolymers and tetrapolymers, has become increasingly complex and costly. Furthermore, fluoropolymers are often categorized as potential “forever chemicals”, raising significant environmental and health concerns due to their environmental persistence. As such, it is highly desirable to rationally design fluorine-free FE polymers with tunable FE properties.

Beyond direct crystallization into polar crystal structures, as observed in PVDF/P(VDF−TrFE) and odd-numbered nylons, a promising strategy is to use highly dipolar molecules to directly induce FE ordering. FE nematic and smectic A liquid crystals (LCs) were realized for rod-like molecules with large dipole moments (μ>~10 Debye or D), a design concept theoretically predicted over a century ago. However, the large dipole moment of these rod-like molecules is achieved by their long rod length, d: μ=qd, where q is the partial charge. The substantial losses and heat generation associated with repeated FE switching of long rod-like molecules highlight the need for an alternative approach. An increase in the partial charge q of small-sized molecular dipoles could minimize these losses while allowing an enhanced dipole moment density (i.e., polarization) with tunable FE properties, but this remains an ongoing challenge.

### SUMMARY

Embodiments described herein relate to fluorine-free ferroelectric polymers and their use in sensor/transducer, piezoelectric, actuation, and energy harvesting applications. We designed fluorine-free ferroelectric and relaxor ferroelectric polymers with small, strongly dipolar sulfonyl groups, whose ferroelectric properties can be tailored by simply varying their chemical structure. The fluorine-free ferroelectric and relaxor ferroelectric polymers can exhibit high polarization and thus remarkable electrostrictive and electrocaloric performance. The unique fluorine-free design of the ferroelectric and relaxor ferroelectric polymers described herein eliminates the environmental concern of polyfluoroalkyl substances for current fluoropolymer-based ferroelectrics. Advantageously, the fluorine-free ferroelectric polymers with sulfonylated side chains show remarkable electroactive performance, including high electroactuation (e.g., piezoelectricity) and electrocaloric effect. Together with their unique fluorine-free chemical structure, these new polymers can offer good opportunities for the development of wearable and biocompatible actuators, coolers, and other advanced flexible electronic devices.

In some embodiments, a fluorine-free ferroelectric polymer includes a main chain and sulfonylated alkyl side chains, e.g., monosulfonylated alkyl side chains or disulfonylated side chains. Each sulfonylated alkyl side chain includes at least one sulfonyl dipole. A sulfonyl group of each sulfonylated alkyl side chain is linked to the main chain with an at least 3 atoms in length aliphatic or heteroaliphatic linker.

In some embodiments, the fluorine-free ferroelectric polymer is mesogen-free and capable of forming layered crystalline or liquid crystalline structures.

In some embodiments, the fluorine-free ferroelectric polymer can have a comb-shaped structure wherein each repeating unit of the main polymer chain includes a sulfonylated alkyl side chain.

In some embodiments, the fluorine-free ferroelectric polymer can include nano- to micro-sized ferroelectric domains.

In some embodiments, the sulfonylated alkyl side chains can have a dipole moment effective to induce strong dipolar interactions, polar/ferroelectric ordering of the polymer, and enhanced electroactive performance of the polymer.

In some embodiments, the fluorine-free ferroelectric polymer can exhibit spontaneous polarization of at least 20 mC/m².

In some embodiments, each sulfonylated alkyl side chain is disulfonylated and includes an odd-numbered alkylene spacer between disulfonyl groups, which results in two substantially parallel sulfonyl dipoles.

In some embodiments, the alkylene spacer between disulfonyl groups of each disulfonylated alkyl side chain has the formula —SO₂(CH₂)ₙSO₂—, where n is an odd number between 3 and 15.

In other embodiments, the alkylene spacer between disulfonyl groups of each disulfonylated alkyl side chain can have the formula —SO₂CH₂CH(R)CH₂SO₂—, and where R is —H or a methyl group.

In some embodiments, each sulfonylated alkyl side chain includes an alkyl tail.

In some embodiments, the alkyl tail has a formula —CH₂(R^{a})(CH₂)ₘCH₃, where R^{a} is —H or a methyl group and m is an integer from 1 to 16.

In other embodiments, the fluorine-free ferroelectric polymer can include one or more repeating units selected from:

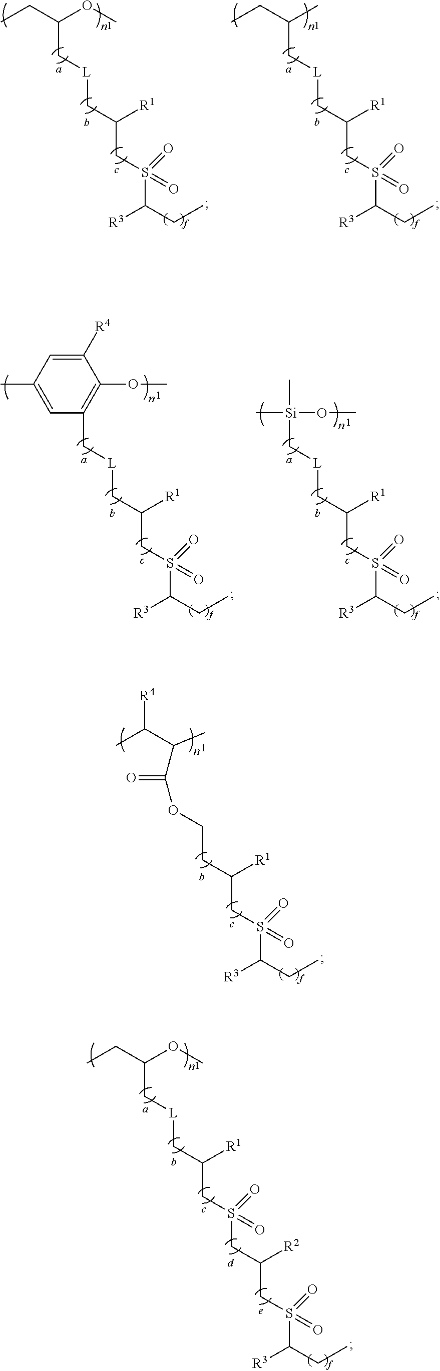

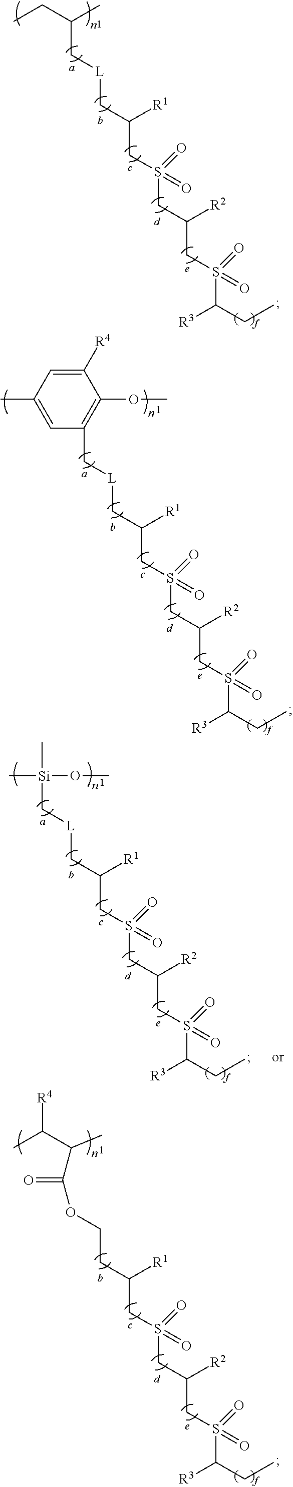

where
n¹ is an integer from 4 to 100;
a, b, c, d, e, and f are each independently an integer from 1 to 16;
L is —S—, —O—, or —CH₂—; and
R¹, R², R³, and R⁴ are each independently H or a methyl group.

In some embodiments, a, b, c, d, and e are each independently an integer from 1 to 3; f is an integer from 1 to 16; L is —S—, or —CH₂—; and R¹, R², R³, and R⁴ are each independently H or methyl.

In other embodiments, the fluorine-free ferroelectric polymer can be selected from:

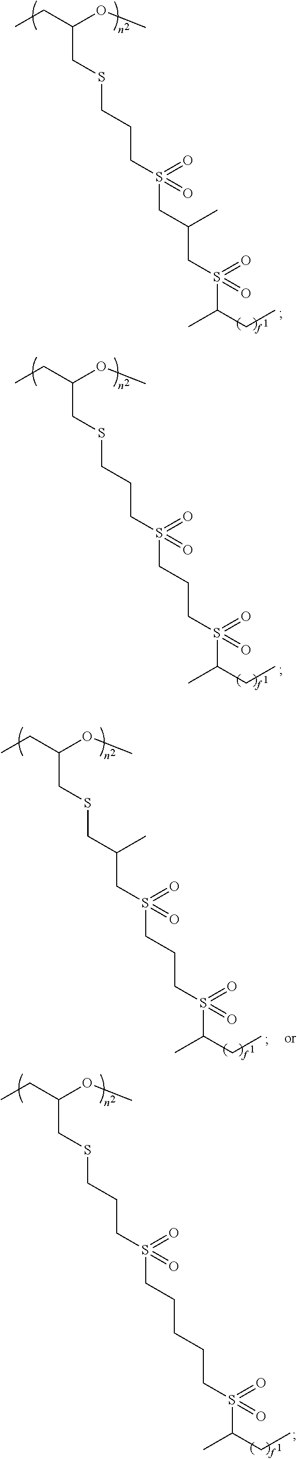

where n² is an integer from 4 to 100; and f¹ is an integer from 1 to 16.

In other embodiments, the fluorine-free ferroelectric polymer is selected from:

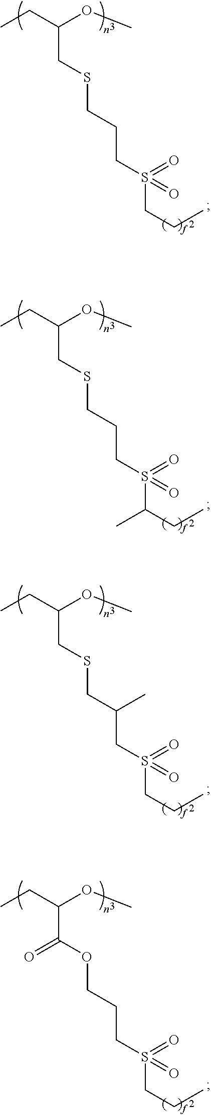

where n³ is an integer from 4 to 100; and f is an integer from 1 to 16.

Other embodiments relate to a piezoelectric material comprising the fluorine-free ferroelectric polymer as described herein.

In some embodiments, the fluorine-free ferroelectric polymer can have a piezoelectric coefficient |d₃₃| of at least about 150 pC/N at room temperature and an electromechanical coupling coefficient k₃₃ of at least about 0.25.

In other embodiments, the fluorine-free ferroelectric polymer can have a piezoelectric coefficient |d₃₃| of at least about 260 pC/N at room temperature and an electromechanical coupling coefficient k₃₃ of at least about 0.6.

In still other embodiments, the fluorine-free ferroelectric polymer can have a piezoelectric coefficient |d₃₃| of at least about 670 pC/N at room temperature and an electromechanical coupling coefficient k₃₃ of at least about 0.7.

In some embodiments, the piezoelectric material can include at least a portion of a sensor, transducer, actuator, cooler, energy harvesting device, or energy storage device.

### BRIEF DESCRIPTION OF THE DRAWINGS

FIGS. 1(A-C) illustrate synthetic routes for (A) FeCP-C3, (B) FeCP-C3(M), and FeCP-MC3.

FIGS. 2(A-F) illustrate structures and phase transitions in FeCP-C3 and FeCP-C3(M). (A) Chemical structures of (i) FeCP-C3 and (ii) FeCP-C3(M) polymers, showing two parallel sulfonyl dipoles in the side chain with a C3 spacer. First cooling and second heating DSC curves of (B) FeCP-C3 and (C) FeCP-C3(M) powder samples. T_{g} is the glass transition temperature. Tₘ and Tₓ are melting and crystallization temperatures. Tᵢ is the isotropization temperature. The insets show the corresponding polarized light microscopy (PLM) images at different temperatures. 2D XRD fiber patterns of (D) FeCP-C3 and (E) FeCP-C3(M) melt-drawn fibers at 25° C. (F) The proposed double-layer structure. Yellow strings represent the aliphatic side chains, light-blue springs are the main chains with 2₁ helical conformation, and small red arrows represent aligned sulfonyl dipoles. Pₛ is the spontaneous polarization from FE ordering of the disulfonyl groups.

FIGS. 3(A-D) illustrate plots showing ferroelectricity of FeCP-C3 and relaxor ferroelectricity of FeCP-C3(M). Temperature-scan BDS results of the real part of the relative permittivity (εr′) for (A) FeCP-C3 and (B) FeCP-C3(M) during cooling at −2° C./min. T_{C} is the Curie temperature. The inset of (A) shows the Curie-Weiss plot for frequency between 30 kHz and 1 MHz. The inset of (B) shows the Vogel-Fulcher fitting of Tₘₐₓ. Bipolar D-E loops of (C) FeCP-C3 and (D) FeCP-C3(M). The inset in (D) shows a gradual decrease of Pᵣ with temperature.

FIGS. 4(A-E) illustrate MD simulations of FeCP-C3 and FeCP-C3(M). MD-simulated full atomistic models of single-layer (A) FeCP-C3 and (B) FeCP-C3(M) with the initial dipole randomization angle, α=π/2. (C) Magnified single side chains for FeCP-C3 and FeCP-C3(M) in the red box in (A) and the blue box in (B), respectively. The magnified side-views of the disulfonyl groups in three layers of stacked molecules are also shown. (D) Simulated dipole moments of the inner and the outer sulfonyl dipoles as a function of the initial dipole randomization angle α (defined in the inset). (E) Free energy as a function of α for FeCP-C3 and FeCP-C3(M).

FIGS. 5(A-C) illustrate structures and phase transitions in FeCP-MC3. (A) Chemical structures of FeCP-MC3 polymers, showing two parallel sulfonyl dipoles in the side chain with a C3 spacer. (B) DSC curves for FeCP-MC3 at 10° C./min scanning rate. (C) Integrated 1D XRD curves of a melt-drawn FeCP-MC3 fiber at 25° C. and 100° C. The side chains are tilted at ~170 with respect to the normal direction of crystalline lamellae, based on the azimuthal scan result at q=13.6 nm⁻¹. The insets show corresponding 2D XRD patterns at 25° C. and 100° C.

FIGS. 6(A-D) illustrate (A) P-E loops for electrically poled FeCP-MC3 at room temperature and 1 Hz. The electric poling was carried out at 100 MV/m (1 Hz) and 50° C. (B) Converse piezoelectric S₃-E loops (1 Hz) and (C) direct piezoelectric charge curves for FeCP-MC3, FeCP-C3, and FeCP-C5, respectively. (D) Comparison of |d₃₃| and k₃₃ for different piezoelectric polymers and ceramics.

FIGS. 7(A-C) illustrate (A) Temperature-scan BDS results of the real part of relative permittivity (εᵣ′) for FeCP-MC3 under different frequencies. (B) Differential dielectric constant (Δεᵣ′) as a function of temperature under different frequencies. (C) Fitting of Tₘₐₓ using Vogel-Fulcher law.

FIGS. 8(A-B) Proposed FE domain structures in semicrystalline (A) FeCP-C3 and (B) FeCP-MC3 with FE crystals, oriented and isotropic amorphous fractions (OAF and IAF). In the OAF of FeCP-MC3, polar nanoregions (PNRs) produce the RFE behavior due to poor molecular packing and weaker interactions

### DETAILED DESCRIPTION

To facilitate the understanding of this invention, a number of terms are defined below. Terms defined herein have meanings as commonly understood by a person of ordinary skill in the areas relevant to the present invention. Terms such as “a”, “an”, and “the” are not intended to refer to only a singular entity but also plural entities and also includes the general class of which a specific example may be used for illustration. The terminology herein is used to describe specific aspects of the invention, but their usage does not delimit the invention, except as outlined in the claims.

Throughout the description, where compositions are described as having, including, or comprising, specific components, it is contemplated that compositions also consist essentially of, or consist of, the recited components. Similarly, where methods or processes are described as having, including, or comprising specific process steps, the processes also consist essentially of, or consist of, the recited processing steps. Further, it should be understood that the order of steps or order for performing certain actions is immaterial so long as the compositions and methods described herein remains operable. Moreover, two or more steps or actions can be conducted simultaneously.

As used herein, the term “about” or “approximately” refers to a quantity, level, value, number, frequency, percentage, dimension, size, amount, weight or length that varies by as much as 15%, 10%, 9%, 8%, 7%, 6%, 5%, 4%, 3%, 2% or 1% to a reference quantity, level, value, number, frequency, percentage, dimension, size, amount, weight or length. In one embodiment, the term “about” or “approximately” refers a range of quantity, level, value, number, frequency, percentage, dimension, size, amount, weight or length ±15%, ±10%, ±9%, ±8%, ±7%, ±6%, ±5%, ±4%, ±3%, ±2%, or ±1% about a reference quantity, level, value, number, frequency, percentage, dimension, size, amount, weight or length.

It is further noted that the claims may be drafted to exclude any optional element. As such, this statement is intended to serve as antecedent basis for use of such exclusive terminology as “solely”, “only” and the like in connection with the recitation of claim elements, or the use of a “negative” limitation. “Optional” or “optionally” means that the subsequently described circumstance may or may not occur, so that the description includes instances where the circumstance occurs and instances where it does not.

Embodiments described herein relate to fluorine-free ferroelectric polymers and their use in sensor/transducer, piezoelectric, actuation, and energy harvesting applications. We designed fluorine-free ferroelectric and relaxor ferroelectric polymers with small, strongly dipolar sulfonyl groups, whose ferroelectric properties can be tailored by simply varying their chemical structure. The fluorine-free ferroelectric and relaxor ferroelectric polymers can exhibit high polarization and thus remarkable electrostrictive and electrocaloric performance. The unique fluorine-free design of the ferroelectric and relaxor ferroelectric polymers described herein eliminates the environmental concern of polyfluoroalkyl substances for current fluoropolymer-based ferroelectrics.

Advantageously, the ferroelectric and relaxor ferroelectric polymers described herein can be mesogen-free but can still form layered crystalline or liquid crystalline structures as well as achieve high polarization because of the highly polarizable sulfonyl groups in the LC state at room temperature (RT). These fluorine-free electroactive ferroelectric polymers with sulfonylated side chains show remarkable electroactive performance, including high electroactuation, piezoelectricity, and electrocaloric effect. Together with their unique fluorine-free chemical structure, these new polymers can offer good opportunities for the development of wearable and biocompatible actuators, coolers, and other advanced flexible electronic devices.

In some embodiments, a fluorine-free ferroelectric polymer includes a main chain and sulfonylated alkyl side chains, e.g., monosulfonylated alkyl side chains or disulfonylated alkyl side chains. Each sulfonylated alkyl side chain includes at least one sulfonyl dipole. A sulfonyl group of each sulfonylated alkyl side chain is linked to the main chain with an at least 3 atoms in length aliphatic or heteroaliphatic linker.

The fluorine-free ferroelectric polymer can be a homopolymer or copolymer. The homopolymer can have a main chain of the same repeating units that each include the sulfonylated alkyl side chain extending from the repeating unit. The copolymer can have a main chain or backbone that includes blocks or sequences of differing repeating units that each include the sulfonylated alkyl side chain extending from the repeating unit. The blocks or sequences of repeating units can be linked together with other blocks or sequences of repeating units to form random, gradient, or block copolymers with the sulfonylated alkyl side chains. These other blocks or sequences of repeating units can comprise, for example, about 5% to about 50% of the copolymer.

In some embodiments, the repeating units can include alkylene repeating units, e.g., ethylene, propylene, styrene, isopropylene, isobutylene, etc., ether repeating units, e.g., ethylene oxide, propylene oxide, arylene oxide, etc., acrylate repeating units, e.g., methacrylate repeating units, or siloxane repeating units.

In other embodiments, the fluorine-free ferroelectric polymer can have a comb-shaped structure wherein each repeating unit of the main polymer chain includes a sulfonylated alkyl side chain.

In some embodiments, the aliphatic or heteroaliphatic linker can be at least 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, or 35 atoms in length and be branched or straight chain. For example, the aliphatic or heteroaliphatic linker can be 3 to 10 atoms in length and include up to 3 heteroatoms selected from S and O.

In some embodiments, the aliphatic or heteroaliphatic linker can be 3 to 10 atoms in length and include up to 3 heteroatoms selected from S and O, and optionally further include a methyl, ethyl, or propyl branch.

In some embodiments, the aliphatic or heteroaliphatic linker can be 3 to 10 atoms in length and optionally include 1 heteroatom selected from S and O, and optionally further include a methyl, ethyl, or propyl branch.

In some embodiments, each sulfonylated alkyl side chain is monosulfonylated.

In other embodiments, each sulfonylated alkyl side chain is disulfonylated and includes an odd-numbered alkylene spacer between disulfonyl groups, which results in two substantially parallel sulfonyl dipoles.

In some embodiments, the alkylene spacer between disulfonyl groups of each disulfonylated alkyl side chain has the formula —SO₂(CH₂)ₙSO₂—, where n is an odd number form 3 to 15. For example, the alkylene spacer between disulfonyl groups of each disulfonylated alkyl side chain can have the formula —SO₂(CH₂)₃SO₂—, —SO₂(CH₂)₅SO₂—, —SO₂(CH₂)₇SO₂—, —SO₂(CH₂)₉SO₂—, —SO₂(CH₂)₁₁SO₂—, —SO₂(CH₂)₁₃SO₂—, or —SO₂(CH₂)₁₅SO₂—.

In other embodiments, the alkylene spacer between disulfonyl groups of each disulfonylated alkyl side chain has the formula —SO₂(CH₂)ₓ—CH(R)—(CH₂)_{y}SO₂—, and where x and y are each independently an integer from 1 to 16, and R is —H or a methyl group.

In some embodiments, x and y are each independently 1, 2, or 3. Preferably, x and y are the same. For example, the alkylene spacer between disulfonyl groups of each disulfonylated alkyl side chain can have the formula —SO₂CH₂CH(R)CH₂SO₂—, —SO₂CH₂CH₂CH(R)CH₂CH₂SO₂—, or —SO₂CH₂CH₂CH₂CH(R)CH₂CH₂CH₂SO₂—, and where R is —H or a methyl group.

In some embodiments, each sulfonylated alkyl side chain includes an alkyl tail linked to a sulfonyl group of the sulfonylated alkyl side chain. For a disulfonylated alkyl side chain, the alkyl tail is linked to a sulfonyl group that is not linked to the main chain, i.e., a sulfonyl group of the disulfonylated alkyl side chain that is distal from the main chain.

In some embodiments, the alkyl tail can have the formula —CH₂(R^{a})(CH₂)mCH₃, where R^{a} is —H or a methyl group and m is an integer from 1 to 16. For example, the alkyl tail each disulfonylated alkyl side chain can have the formula —CH₂(R^{a})CH₂CH₃, —CH₂(R^{a})(CH₂)₂CH₃, —CH₂(R^{a})(CH₂)₃CH₃, —CH₂(R^{a})(CH₂)₄CH₃, —CH₂(R^{a})(CH₂)₂CH₃, CH₂(R^{a})(CH₂)₄CH₃, —CH₂(R^{a})(CH₂)₅CH₃, —CH₂(R^{a})(CH₂)₆CH₃, —CH₂(R^{a})(CH₂)₇CH₃, —CH₂(R^{a})(CH₂)₈CH₃, —CH₂(R^{a})(CH₂)₉CH₃, —CH₂(R^{a})(CH₂)₁₀CH₃, —CH₂(R^{a})(CH₂)₁₁CH₃, —CH₂(R^{a})(CH₂)₁₂CH₃, —CH₂(R^{a})(CH₂)₁₃CH₃, —CH₂(R^{a})(CH₂)₁₄CH₃, —CH₂(R^{a})(CH₂)₁₅CH₃, or —CH₂(R^{a})(CH₂)₁₄CH₃, —CH₂(R^{a})(CH₂)₁₅CH₃, or —CH₂(R^{a})(CH₂)₁₆CH₃, and where R^{a} is —H or a methyl group.

In some embodiments, the fluorine-free ferroelectric polymer can include one or more repeating units selected from:

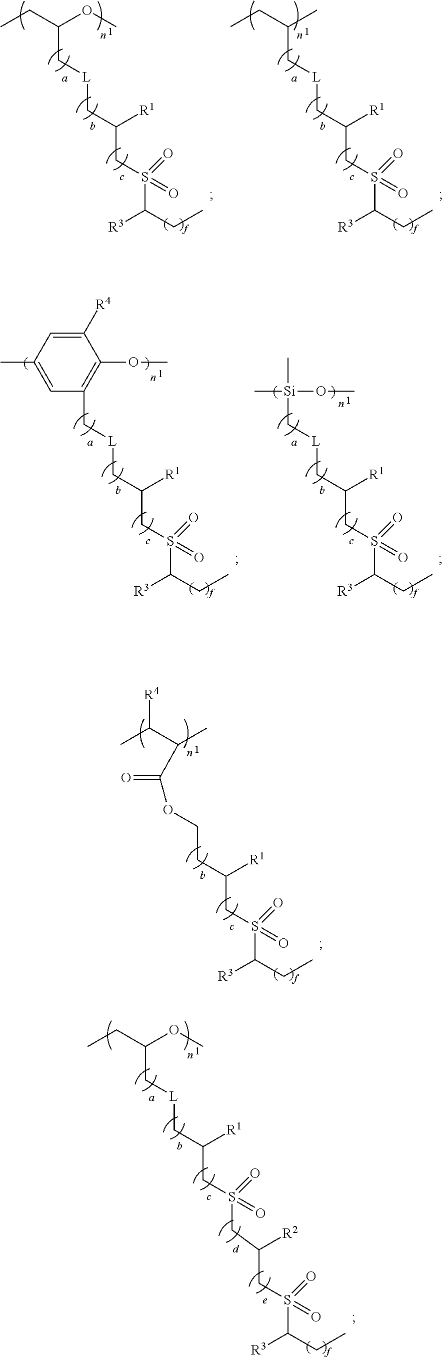

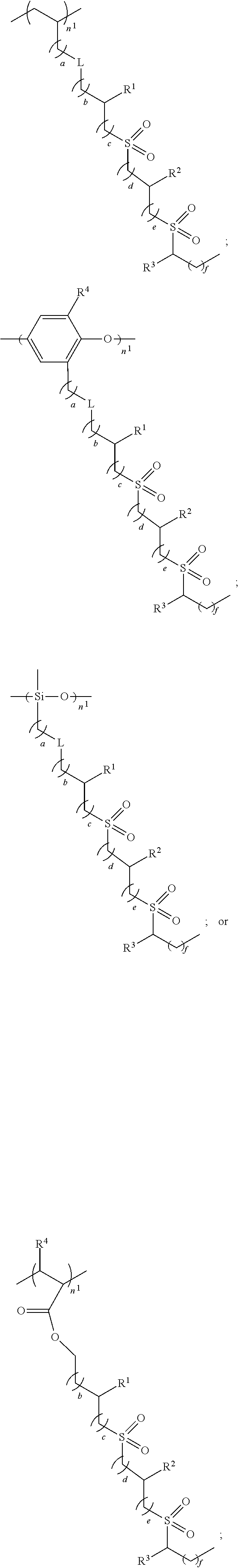

where
n¹ is an integer from 4 to 100;
a, b, c, d, e, and f are each independently an integer from 1 to 16;
L is —S—, —O—, or —CH₂—; and
R¹, R², R³, and R⁴ are each independently H or a methyl group.

In some embodiments, a, b, c, d, and e are each independently an integer from 1 to 7.

In other embodiments, a, b, c, d, and e are each independently an integer from 1 to 3; f is an integer from 1 to 16; L is —S—, or —CH₂—; R¹, R², R³, and R⁴ are each independently H or methyl, and n¹ is an integer from 4 to 100.

In still other embodiments, the fluorine-free ferroelectric polymer can be selected from:

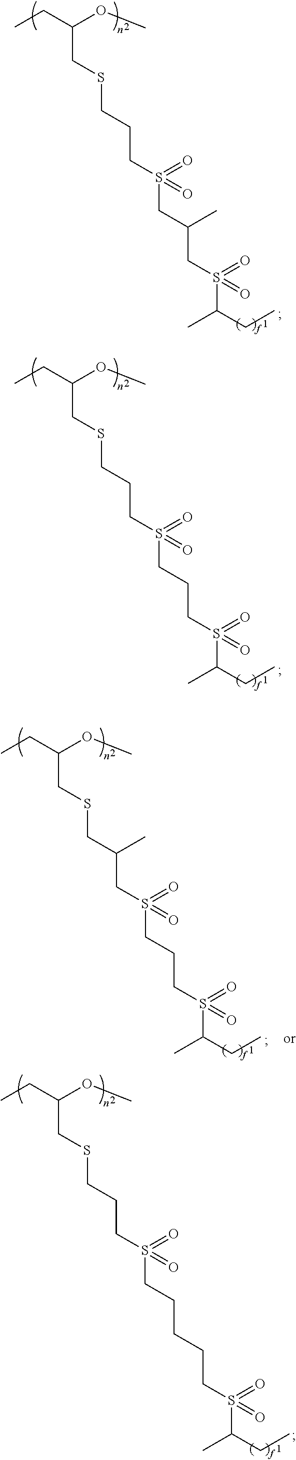

where n² is an integer from 4 to 100; and f 1 is an integer from 1 to 10.

In other embodiments, the fluorine-free ferroelectric polymer is selected from:

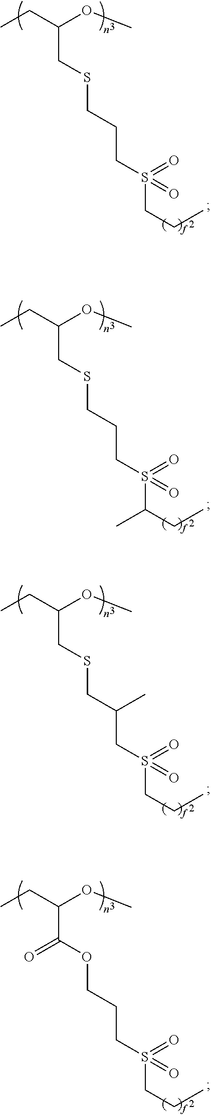

where n³ is an integer from 4 to 100; and f² is an integer from 1 to 16.

In some embodiments, the fluorine-free ferroelectric polymer can be a fluorine-free ferroelectric homopolymer that has a number average molecular weight (Mn) of about 80,000 g/mol to about 200,000 g/mol, for example, a Mn of about 80,000 g/mol to about 180,000 g/mol, a Mn of about 80,000 g/mol to about 180,000 g/mol, a Mn of about 80,000 g/mol to about 160,000 g/mol, a Mn of about 80,000 g/mol to about 140,000 g/mol, a Mn of about 80,000 g/mol to about 120,000 g/mol, a Mn of about 80,000 g/mol to about 100,000 g/mol, a Mn of about 100,000 g/mol to about 200,000 g/mol, a Mn of about 120,000 g/mol to about 200,000 g/mol, a Mn of about 140,000 g/mol to about 200,000 g/mol, a Mn of about 160,000 g/mol to about 200,000 g/mol, or a Mn of about 180,000 g/mol to about 200,000 g/mol, including ranges between any of the foregoing values.

In some embodiments, the fluorine-free ferroelectric homopolymer can have a weight average molecular weight (Mw) of about 200,000 g/mol to about 600,000 g/mol, for example, a Mw of about 200,000 g/mol to about 550,000 g/mol, a Mw of about 200,000 g/mol to about 500,000 g/mol, a Mw of about 200,000 g/mol to about 450,000 g/mol, a Mw of about 200,000 g/mol to about 400,000 g/mol, a Mw of about 200,000 g/mol to about 350,000 g/mol, a Mw of about 200,000 g/mol to about 300,000 g/mol, a Mn of about 250,000 g/mol to about 600,000 g/mol, a Mw of about 300,000 g/mol to about 600,000 g/mol, a Mw of about 350,000 g/mol to about 600,000 g/mol, a Mw of about 400,000 g/mol to about 600,000 g/mol, a Mw of about 450,000 g/mol to about 600,000 g/mol, or a Mw of about 500,000 g/mol to about 600,000 g/mol, including ranges between any of the foregoing values.

In some embodiments, the molecular weight distribution for the fluorine-free ferroelectric polymer may be independently chosen from mono-disperse, bimodal, or polydisperse. The fluorine-free ferroelectric polymer (e.g., a high molecular weight polymer) having a bimodal molecular weight distribution may be characterized by two molecular weight distribution maxima, one in a low(er) molecular weight region and one in a high(er) molecular weight region.

The polydispersity (or heterogeneity index) is a measure of the broadness of a molecular weight distribution of the fluorine-free ferroelectric polymer and may be used to characterize a polymer composition. The polydispersity index (PDI) may be calculated as the ratio of weight average molecular weight (Mw) to number average molecular weight (Mn) of a polymer sample, i.e., PDI=Mw/Mn. In some embodiments, the fluorine-free ferroelectric polymer may have a PDI of about 2.0 to about 4.0, for example, a PDI of about 2.4 to about 4.0, a PDI of about 2.8 to about 4.0, a PDI of about 3.2 to about 4.0, a PDI of about 3.6 to about 4.0, a PDI of about 2.0 to about 3.6, a PDI of about 2.0 to about 3.2, a PDI of about 2.0 to about 2.8, or a PDI of about 2.0 to about 2.4, including ranges between any of the foregoing values.

In some embodiments, the fluorine-free ferroelectric polymer is mesogen-free and capable of forming layered crystalline or liquid crystalline structures.

In still other embodiment, the fluorine-free ferroelectric polymer can have a crystalline content or crystallinity of about 40% to about 60%, for example, a crystalline content of about 45% to about 60%, about 50% to about 60%, about 55% to about 60%, about 40% to about 55%, about 40% to about 50%, or about 40% to about 45%, including ranges between any of the foregoing values.

In some embodiments, the fluorine-free ferroelectric polymer can include nano- to micro-sized ferroelectric domains.

In other embodiments, the fluorine-free ferroelectric polymer can exhibit spontaneous polarization of at least 20 mC/m², for example, about 20 mC/m² to about 40 mC/m².

Other embodiments relate to a piezoelectric material comprising the fluorine-free ferroelectric polymer as described herein.

In some embodiments, the fluorine-free ferroelectric polymer of the piezoelectric material has a piezoelectric coefficient |d₃₃| of at least about 150 pC/N at room temperature and an electromechanical coupling coefficient k₃₃ of at least about 0.25.

In other embodiments, the fluorine-free ferroelectric polymer of the piezoelectric material can have a piezoelectric coefficient |d₃₃| of at least about 260 pC/N at room temperature and an electromechanical coupling coefficient k₃₃ of at least about 0.6.

In still other embodiments, the fluorine-free ferroelectric polymer of the piezoelectric material can have a piezoelectric coefficient |d₃₃| of at least about 670 pC/N at room temperature and an electromechanical coupling coefficient k₃₃ of at least about 0.7.

In some embodiments, the piezoelectric material can include at least a portion of a sensor, transducer, actuator, cooler, energy harvesting device, or energy storage device. The environmental-friendly nature of the fluorine-free ferroelectric polymer makes them particularly promising for diverse applications, including wearable and biocompatible actuators, thermal management devices, and next-generation flexible electronics.

The following examples are included to demonstrate various aspects of the invention. Those skilled in the art should, in light of the present disclosure, appreciate that many changes can be made in the specific aspects which are disclosed and still obtain a like or similar result without departing from the spirit and scope of the invention.

### Example 1

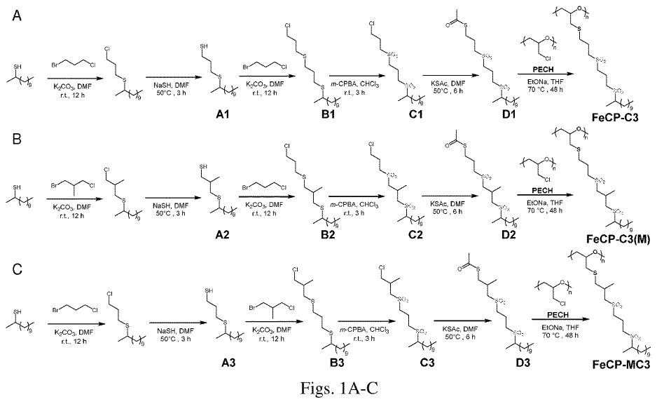

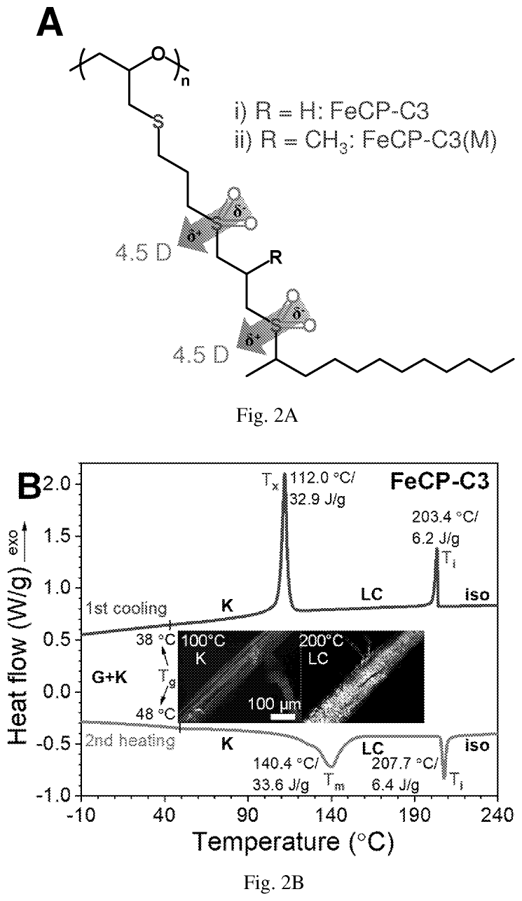

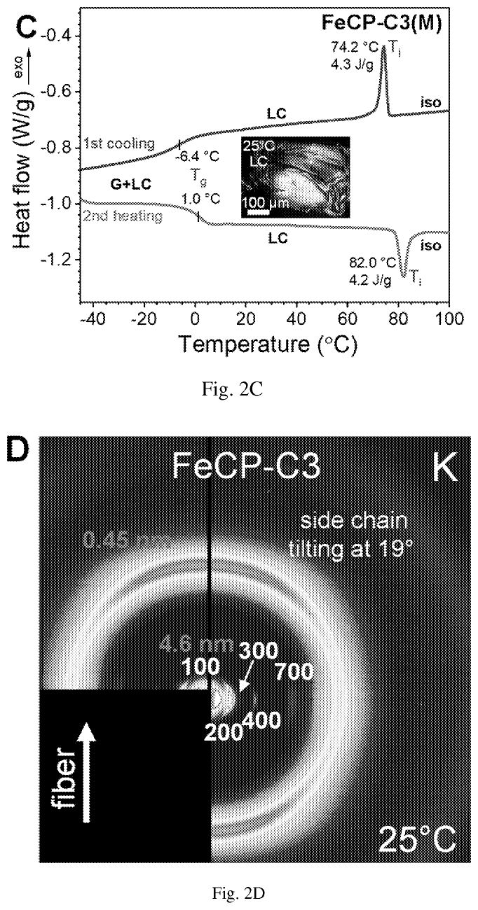

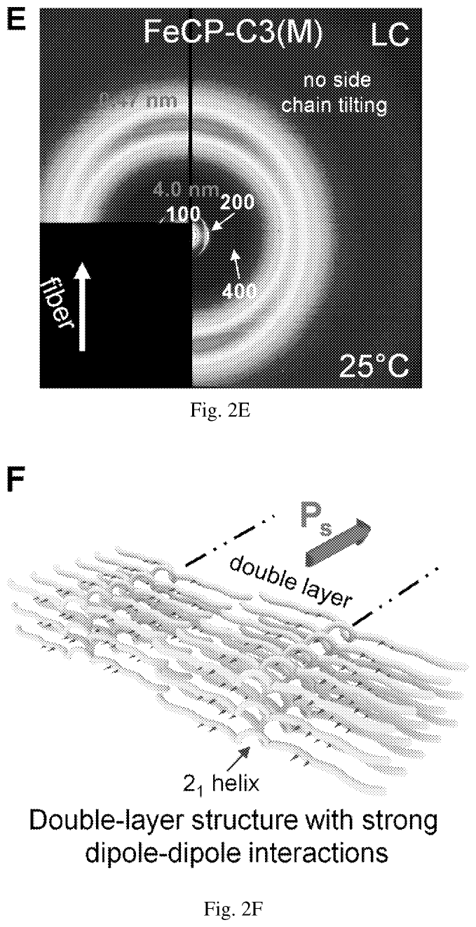

This Example describes the design of fluorine-free ferroelectric (FE) polymers with small-sized, highly dipolar sulfonyl groups. Their FE properties can be tailored by simply varying the chemical structure. These polymers feature a comb-shaped structure with a polyoxypropylene main chain and disulfonylated alkyl side chains with a C3 spacer (FIG. 2A, FIG. 1A-B for synthesis). The overall dipole moment of two sulfonyl groups in each side chain could reach as high as 9 Debye (D, i.e., 4.5 D for each sulfonyl group), when the C3 spacer adopts a zig-zag conformation. We hypothesize that such a large dipole moment should favor FE ordering. By manipulating the methyl branch in the C3 spacer, the dipole-dipole interactions can be tailored to achieve either normal ferroelectricity (for FeCP-C3 without the methyl branch) or relaxor ferroelectricity (RFE, for FeCP-C3(M) with the methyl branch).

### Materials and Methods

### Materials

1-Chloro-3-bromopropane (99%), 1-chloro-3-bromo-2-methylpropane (99%), tetrahydrofuran (THF, anhydrous), potassium thioacetate (KSAc, 97%), and sodium hydride (NaH, 60% dispersion in paraffin liquid) were purchased from TCI America. Polyepichlorohydrin (PECH) and sodium hydrosulfide hydrate (NaSH·xH2O, ≥60%) were purchased from Millipore-Sigma. 3-Chloroperoxybenzoic acid (m-CPBA, 70-75%, balance 3-chlorobenzoic acid and water), phosphorus tribromide (99%), and N,N-dimethylformamide (DMF, 99.8% extra dry) were purchased from Acros Organics or Acros. 1-Dodecene (96%) and 3 Å molecular sieve beads (8-12 mesh) were purchased from Alfa Aesar. Hexane (mixed isomers, certified ACS), chloroform (certified ACS), methanol (certified ACS), ethyl acetate (EA, certified ACS), ethanol (absolute, certified ACS), potassium iodide (KI, certified ACS), sodium sulfate (anhydrous, certified ACS), alumina A540 (80-200 mesh powder), and deionized (DI) water were purchased from Fisher Chemical or Thermo Scientific. Chloroform-d (CDCl₃, 99.8 atom % D) and dimethyl sulfoxide-d6 (DMSO-d6, 99.8 atom % D) were purchased from Cambridge Isotope Laboratories. Ethanol and THF were dried with activated 3 Å molecular sieves before use. All other chemicals and solvents were used as received without further purification. Liquid crystal (LC) cells with transparent indium tin oxide (ITO) electrodes are either purchased from Instec, Inc or home-made by sandwiching two ITO-coated glass slides.

### Instrumentation and Characterization Methods

Proton (¹H, 500 MHz) and carbon-13 (¹³C, 126 MHz) nuclear magnetic resonance (NMR) spectra were recorded on a Bruker Ascend Advance III HD™ NMR spectrometer using CDCl₃ or DMSO-d6 as the solvent and were referenced to the residual solvent peaks (CDCl₃: δ=7.26 ppm for ¹H NMR and δ=77.16 ppm for ¹³C NMR; DMSO-d6: δ=2.50 ppm for ¹H NMR and δ=39.52 ppm for ¹³C NMR).

Molecular weight and dispersity of the synthesized polymers were determined using a PL-GPC 20 (an integrated size exclusion chromatography (SEC) system from Polymer Laboratories, Inc.) at ambient conditions. The instrument was equipped with a Knauer K-2301 refractive index detector, one PL gel 5 μm guard column (50×7.5 mm), and two PL gel 5 μm mixed-C columns (each 300×7.5 mm, linear molecular weight range of 200-2,000,000 Da). ACS certified chloroform was used as the eluent after filtration through a 0.45 μm filter. The flow rate was 1.0 mL/min in the analysis. The SEC system was calibrated with a set of narrow dispersity polystyrene (PS) standards from Scientific Polymer Products, Inc. (Ontario, NY). Polymer samples were dissolved in chloroform by heating in an oil bath at 48° C. for 24 h, and the solutions were filtered through a 0.45 m hydrophilic PTFE filter before injection into the SEC system for analysis. The data were processed using the Cirrus™ SEC software (Polymer Laboratories, Inc.) to give number-average molecular weight (M_{n,SEC}) and dispersity (Ð) relative to linear PS standards.

The heating decomposition experiments were carried out using a TA Instruments thermogravimetric analysis (TGA) 500 with dry nitrogen as the purge gas. For each run, the sample (about 5 mg) was heated from 50 to 800° C. at a heating rate of 10° C./min.

Differential scanning calorimetry (DSC) measurements were carried out on a TA Instruments Discovery DSC 250. For each run, approximately 5 mg of sample was scanned at a rate of 10° C./min under a dry nitrogen gas flow (50 mL/min). The upper limit temperature for each sample scan was at least 50° C. lower than the 95% decomposition temperature (330° C.), which was determined by TGA.

Birefringence of polymers was observed under an Olympus BX60 polarized light microscope (PLM), equipped with an Instec HCS402 hot stage (Instec, Inc., Boulder, CO). Digital images were recorded using a 16-megapixel AmScope digital camera.

Synchrotron X-ray diffraction (XRD) experiments of polymers were carried out at the 11-BM Complex Materials Scattering (CMS) beamline of National Synchrotron Light Source II (NSLS-II), Brookhaven National Laboratory (BNL). The monochromatized X-ray wavelength was 0.07293 nm (17.0 keV). An in-vacuum Pilatus 800K detector (Dectris, Baden-Dättwil, Switzerland) with a pixel size of 0.172 mm was used for data collection. The sample-to-detector distance was 259 mm, which was calibrated using silver behenate with the first-order reflection at a scattering vector q=1.076 nm⁻¹ [q=(4π sin θ)/λ with θ being the half-scattering angle]. The typical data acquisition time was 30 s. A self-built hot stage was used for temperature control. One-dimensional (1D) XRD curves were obtained by integration of the corresponding two-dimensional (2D) patterns using the Igor software with Irene & Nika plugin developed by Argonne National Laboratory.

Additional 2D powder WAXD experiments were performed using a Rigaku MacroMax 002⁺ equipped with a Confocal Max-Flux® optic and a microfocus X-ray tube source operating at 45 kV and 0.88 mA. The X-ray wavelength was 0.15418 nm (Cu Kα). The WAXD patterns were collected using a Fujifilm image plate scanned by a Cytiva Amersham Typhoon scanner at a resolution of 50 m/pixel. 1D WAXD curves were obtained by integrating the corresponding 2D WAXD patterns radially using the Polar software developed by Stonybrook Technology and Applied Research, Inc.

Dynamic mechanical analysis (DMA) was performed on a TA-Q800 DMA apparatus in the tension mode. Heating rate was 2° C. min⁻¹ and the frequency of applied dynamic force was from 1 to 100 Hz.

Broadband dielectric spectroscopy (BDS) tests were performed on a Novocontrol Concept 80 broadband dielectric spectrometer equipped with a temperature control system (Novocontrol Technologies, Montabaur, Germany). The heating and cooling rates were 2° C./min. The applied root-mean-square (rms) voltage was 0.1 Vrms.

Electric displacement-electric field (D-E) loops were measured using a Radiant Technology Premiere II ferroelectric (FE) tester at different frequencies using a 1 Hz sinusoidal wave function. Polymer thin films were sputter-coated with an Au (~10 nm) electrode with a circular area of 7.06 mm². A home-made D-E loop fixture was used for electrical connection, and the entire fixture was immersed in a silicone oil bath to avoid corona discharge in air. The temperature was controlled using a ChemGlass CG-1999V-10 hot plate (Vineland, NJ). AC electronic conduction was subtracted according to our previous report.

### Molecular Dynamics (MD) Simulation

In the first step, a single chain containing a 2₁ helical conformation and 24 side chains was created using the Avogadro-2 software package. The backbone of the molecule was oriented along the x-axis, and the side chains were oriented along they-axis. The entire molecule lay in the xy plane with 12 side chains pointing to the positive y-direction, and the remaining 12 side chains pointing in the negative y-direction. The separation distance between neighboring side chains was fixed at 0.47 nm (i.e., the experimental average inter-side chain distance). At both ends of the molecule, we implemented C11 alkyl chains to fix the 2₁ helical conformation of the main chain during the MD simulation. The geometry of the newly created molecule was equilibrated using the built-in OpenBabel package with the GAFF force field at room temperature (RT). The optimized molecule consisted of 1841 atoms. The molecular structure (partial charges of atoms, bonding, angular, and dihedral angles) were stored in the SyByl mol2 (for the partial atomic charges and bonding data) and LAMMPS data format (lmpdat, for the bond-bond angle and torsional angle data) files. To achieve a dipole moment of 4.5 D for the sulfonyl group, the charges on the S and O atoms in the SO₂ triplet were changed to 1.31e and −0.655e, respectively.

In the second step, the stored mol2 and lmpdat files were used to create several stacks of 10 molecules along the z-axis with the intermolecular separation distance h varying in the range 0.4 to 0.54 nm. The SO₂ dipole moment of 4.5 D makes the dipole-dipole interactions so strong that the molecules were easily trapped in certain local energy minima, preventing the system from reaching a global energy minimum. To overcome such an interlocking issue for strongly dipolar molecules, an initial dipole randomization process was implemented for each molecular stack. At the beginning, the orientation of SO₂ dipoles was randomized by implementing a rotation of the SO₂ dipole around the host side chain by a random angle in the range of 0 to α, which is the initial dipole randomization angle. We considered 5 different values for the randomization angle α. 0, π2, π, 3π2, and 2π.

In the last step, all dipole-randomized stacks of 10 molecules were used in the all-atomistic MD simulations, first, for the equilibration during 1 ns short runs, and then, for the 100 ns production runs. The repeat units of the same chain interact with each other through the specific two-body bond-stretching potential U_{bond}, three-body angle-bending potential U_{angle}, and four-body dihedral angle bending potential U_{dihedral}. The repeat units between different molecules interact through the Coulomb and van der Waals interactions.

During simulations, the backbone of each molecule was immobilized to focus only on the dynamics and reorientation of the side chains with SO₂ dipoles. The total energy of the simulated system was calculated as a sum of its bond, angular, torsional, and electrostatic energies. The Helmholtz free energy was also calculated for the simulated system. MD runs with a Langevin thermostat having a friction coefficient γ=2 ps⁻¹ and a Gaussian white-noise force of strength 6 kBTγ were performed in a constant NVT ensemble. The equations of motion were integrated using the velocity Verlet algorithm with a time step of 1 fs. We imposed standard periodic boundary conditions by filling space with translational replicas of the fundamental cell in the x and y directions. The long-range electrostatic interactions between charged particles were handled using the standard Lekner summation algorithm.

### Synthesis Procedures

Synthesis procedures for FeCP-C3 and FeCP-C3(M) are shown in FIGS. 1(A-B). The syntheses of compounds A1 and A2 are described in M.-H. Kwok et al., Achieving high permittivity paraelectric behavior in mesogen-free sulfonylated chiral polyethers with smectic C liquid crystalline self-assembly. Macromolecules 56, 1863-1874 (2023), which is herein incorporated by reference in its entirety.

Compound B1. Compound A1 (5.0 g, 17.2 mmol), 1-chloro-3-bromopropane (8.0 g, 50.8 mmol), and K₂CO₃ (7.0 g, 50.7 mmol) were added into a 250 mL flask along with DMF (50 mL) as the solvent. After the reaction mixture was stirred under argon at ambient temperature for 12 h, it was poured into water (500 mL), and the product was extracted with hexane three times (200 mL×3). The organic phases were combined and washed with deionized water three times (200 mL×3) and then dried over anhydrous Na₂SO₄. After the evaporation of hexane via a rotary evaporator, the remaining liquid was dried in a vacuum oven at 40° C. for 3 days. The product was obtained as a colorless clear liquid (5.9 g, 93.4% yield) and used for the next step reaction without further purification. ¹H NMR (500 MHz, CDCl₃), δ (ppm)=3.66 (t, ClCH₂—, 2H), 2.69-2.56 (m, —SCH₂— and —SCH(CH₃)CH₂—, 7H), 2.07-2.01 (m, ClCH₂CH₂CH₂S—, 2H), 1.89-1.81 (m, —SCH₂CH₂CH₂S—, 2H), 1.59-1.49 (m, —SCH(CH₃)CH₂CH₂—, 1H), 1.48-1.41 (m, —SCH(CH₃)CH₂CH₂—, 1H), 1.33-1.18 (m, —SCH(CH₃)CH₂(CH₂)8CH₃, 19H), 0.88 (t, —CH₂CH₃, 3H).

Compound B2. The synthetic procedure is similar to that for compound B1. The product was obtained as a colorless clear liquid. ¹H NMR (500 MHz, CDCl₃), δ (ppm)=3.66 (t, ClCH₂—, 2H), 2.74-2.39 (m, —SCH₂— and —SCH(CH₃)CH₂—, 7H), 2.07-2.02 (m, ClCH₂CH₂CH₂S—, 2H), 1.91-1.83 (m, —SCH₂CH(CH₃)CH₂S—, 1H), 1.59-1.49 (m, —SCH(CH₃)CH₂CH₂—, 1H), 1.48-1.41 (m, —SCH(CH₃)CH₂CH₂—, 1H), 1.34-1.19 (m, —SCH(CH₃)CH₂(CH₂)₈CH₃, 19H), 1.11-1.04 (d, —SCH₂CH(CH₃)CH₂S—, 3H), 0.88 (t, —CH₂CH₃, 3H).

Compound C1. Compound B1 (5 g, 13.6 mmol) was dissolved with chloroform (100 mL) in a 500 mL flask and stirred in an ice-water bath for 30 min. Then, m-CPBA (20.5 g, 70% purity, 83.2 mmol) was slowly added into the flask. The mixture was stirred at RT for 3 h. After chloroform was removed via a rotary evaporator, 1 M NaOH solution was used to wash away excess m-CPBA and the by-product, m-chlorobenzoic acid (m-CBA). The residue in the flask was dissolved in chloroform (100 mL) and transferred into a separatory funnel. The organic phase was washed with deionized water 3 times (200 mL×3) and dried over anhydrous Na2SO4. After the evaporation of chloroform via a rotary evaporator, the remaining liquid was dried in a vacuum oven at 40° C. overnight. The product was obtained as a white solid (5.3 g, 90.3% yield) and used directly for the next step reaction without further purification. ¹H NMR (500 MHz, CDCl₃), δ (ppm)=3.70 (t, ClCH₂—, 2H), 3.27 (t, ClCH₂CH₂CH₂SO₂CH₂—, 2H), 3.22-3.12 (m, SO₂CH₂CH₂CH₂SO₂CH(CH₃)CH₂—, 4H), 2.96-2.88 (m, —SO₂CH₂CH₂CH₂SO₂CH(CH₃)CH₂—, 1H), 2.49-2.41 (m, —SO₂CH₂CH₂CH₂SO₂CH(CH₃)CH₂—, 2H), 2.36-2.29 (m, ClCH₂CH₂CH₂SO₂CH₂—, 2H), 2.05-1.93 (m, —SO₂CH₂CH₂CH₂SO₂CH(CH₃)CH₂—, 1H), 1.53-1.45 (m, —SO₂CH₂CH₂CH₂SO₂CH(CH₃)CH₂—, 1H), 1.39-1.37 (d, —SO₂CH₂CH₂CH₂SO₂CH(CH₃)CH₂—, 3H), 1.34-1.19 (m, —SO₂CH(CH₃)CH₂(CH₂)₈CH₃, 16H), 0.88 (t, —CH₂CH₂CH₃, 3H).

Compound C2. The synthetic procedure is similar to that for compound C1. The product was obtained as a clear liquid. ¹H NMR (500 MHz, CDCl₃), δ (ppm)=3.69 (m, ClCH₂—, 2H), 3.57-3.49 (m, ClCH₂CH₂CH₂SO₂CH₂—, 1H), 3.33-3.26 (m, ClCH₂CH₂CH₂SO₂CH₂—, 1H), 3.22 (t, ClCH₂CH₂CH₂SO₂CH₂—, 2H), 3.05-3.01 (m, —CH₂CH(CH₃)CH₂SO₂CH(CH₃)CH₂—, 1H), 2.98-2.85 (m, —CH₂CH(CH₃)CH₂SO₂CH(CH₃)CH₂—, 3H), 2.37-2.28 (m, ClCH₂CH₂CH₂SO₂CH₂—, 2H), 2.05-1.93 (m, —SO₂CH₂CH(CH₃)CH₂SO₂CH(CH₃)CH₂—, 1H), 1.53-1.45 (m, —SO₂CH₂CH(CH₃)CH₂SO₂CH(CH₃)CH₂—, 1H), 1.44-1.40 (d, —SO₂CH₂CH(CH₃)CH₂SO₂CH(CH₃)CH₂—, 3H), 1.40-1.36 (m, —SO₂CH₂CH(CH₃)CH₂SO₂CH(CH₃)CH₂—, 3H), 1.34-1.19 (m, —SO₂CH(CH₃)CH₂(CH₂)₈CH₃, 16H), 0.88 (t, —CH₂CH₂CH₃, 3H).

Compound D1. Compound C1 (5.1 g, 11.8 mmol) was dissolved by DMF (50 mL) in a 250 mL flask, and KSAc (2.0 g, 17.5 mmol) was added into the flask. The mixture was stirred at RT for 15 min with N₂ degassing. Then, the mixture was heated to 50° C. for 6 h with a gentle N₂ flow. After reaction, the mixture was poured into water (200 mL), extracted with chloroform for 3 times (100 mL×3). Then, the organic phase was combined and dried over anhydrous Na₂SO₄. After the evaporation of chloroform via a rotary evaporator, the remaining liquid was carefully purified by a silica gel column twice with a mixture of ethyl acetate and hexane as eluent (v:v=1:5). The purified product was white solid (3.8 g, 74.4%). ¹H NMR (500 MHz, DMSO-d6), δ (ppm)=3.29-3.08 (m, —CH₂SO₂CH₂CH₂CH₂SO₂CH(CH₃)CH₂—, 7H), 2.94 (t, CH₃COSCH₂CH₂CH₂SO₂—, 2H), 2.34 (s, CH₃COSCH₂CH₂CH₂SO₂—, 3H), 2.10-2.04 (m, —CH₂SO₂CH₂CH₂CH₂SO₂CH(CH₃)CH₂—, 2H), 1.96-1.88 (m, CH₃COSCH₂CH₂CH₂SO₂—, 2H), 1.87-1.78 (m, —CH₂CH₂CH₂SO₂CH(CH₃)CH₂—, 1H), 1.38-1.32 (m, —CH₂CH₂CH₂SO₂CH(CH₃)CH₂—, 1H), 1.31-1.19 (m, —CH₂CH₂CH₂SO₂CH(CH₃)CH₂(CH₂)₈CH₃, 19H), 0.85 (t, —CH₂CH₂CH₃, 3H). ¹³C NMR (126 MHz, DMSO-d6), δ (ppm)=195.12, 56.20, 50.47, 49.96, 46.76, 31.30, 30.59, 28.96, 28.97, 28.81, 28.71, 28.04, 26.95, 25.75, 22.10, 22.06, 14.67, 13.97, 12.42, 10.71.

Compound D2. The synthetic procedure is similar to that for compound D1. The product was obtained as a lightly yellow liquid. ¹H NMR (500 MHz, DMSO-d6), δ (ppm)=3.39-3.32 (m, —SO₂CH₂CH(CH₃)CH₂SO₂CH(CH₃)CH₂—, 2H), 3.20-3.12 (m, —CH₂SO₂CH₂CH(CH₃)CH₂SO₂CH(CH₃)CH₂—, 3H), 3.10-3.01 (m, —SO₂CH₂CH(CH₃)CH₂SO₂CH(CH₃)CH₂—, 2H), 2.95 (t, CH₃COSCH₂CH₂CH₂SO₂—, 2H), 2.73-2.65 (m, —SO₂CH₂CH(CH₃)CH₂SO₂CH(CH₃)CH₂—, 1H), 2.34 (s, CH₃COSCH₂CH₂CH₂SO₂—, 3H), 1.96-1.88 (m, CH₃COSCH₂CH₂CH₂SO₂—, 2H), 1.87-1.78 (m, —CH₂CH(CH₃)CH₂SO₂CH(CH₃)CH₂—, 1H), 1.38-1.32 (m, —CH₂CH(CH₃)CH₂SO₂CH(CH₃)CH₂—, 1H), 1.31-1.19 (m, —CH₂CH(CH₃)CH₂SO₂CH(CH₃)CH₂(CH₂)₈CH₃, 22H), 0.85 (t, —CH₂CH₂CH₃, 3H). ¹³C NMR (126 MHz, DMSO-d6), δ (ppm)=195.10, 195.08, 57.39, 56.29, 56.25, 53.90, 52.96, 52.89, 51.76, 51.74, 31.29, 30.58, 28.98, 28.96, 28.79, 28.71, 28.16, 28.09, 26.94, 25.78, 23.13, 23.10, 22.10, 20.03, 19.91, 19.88, 13.96, 12.44, 12.34, 10.84, 10.78.

FeCP-C3. NaH (135.0 mg, ~60 wt. % in paraffin oil, 3.4 mmol) was added into 50 mL anhydrous THF in a 250 mL three-neck flask equipped with a gas flow control adaptor and a condenser. Anhydrous ethanol (1.0 mL) was added dropwise into the flask at RT with stirring and the mixture was degassed with N₂ for 1 h. Then, compound D1 (1.5 g, 3.2 mmol) was slowly added into the flask with vigorous stirring at RT for 1 h. The flask was heated to 70° C., and PECH (190.0 mg, 2.0 mmol polymer repeating unit) was added into the flask. The reaction continued at 70° C. under the N₂ atmosphere for 48 h. After reaction, deionized water (200 mL) was added into the flask and the precipitated crude polymer was collected. The crude polymer was dissolved in ~5 mL chloroform and precipitated in methanol (100 mL) five times for purification. The purified polymer was soaked in DI water (50 mL) at 40° C. for one week with daily change of DI water to minimize ion contamination. The final polymer was obtained as a white solid (745.0 mg, 75% yield). The substitution rate was >95% based on the integration values of different protons. M_{n,SEC}=102.9 kDa and Ð=2.78. ¹H NMR (500 MHz, CDCl₃), δ (ppm)=3.76-3.53 (m, —CH₂CH(CH₂)O—, 3H), 3.26
(t, —SO₂CH₂CH₂CH₂SO₂CH(CH₃)CH₂—, 2H), 3.22-3.11 (m, —SO₂CH₂CH₂CH₂SO₂CH(CH₃)CH₂—, —SCH₂CH₂CH₂SO₂CH₂— 4H), 2.99-2.90 (m, —SO₂CH₂CH₂CH₂SO₂CH(CH₃)CH₂—, 1H), 2.83-2.61 (m, —CH₂SCH₂CH₂CH₂SO₂—, 4H), 2.42-2.31 (m, —SO₂CH₂CH₂CH₂SO₂CH(CH₃)CH₂—, 2H), 2.17-2.01 (m, —SCH₂CH₂CH₂SO₂CH₂—, 2H), 2.05-1.93 (m, —SO₂CH₂CH₂CH₂SO₂CH(CH₃)CH₂—, 1H), 1.53-1.45 (m, —SO₂CH₂CH₂CH₂SO₂CH(CH₃)CH₂—, 1H), 1.38-1.37 (d, —SO₂CH₂CH₂CH₂SO₂CH(CH₃)CH₂—, 3H), 1.34-1.19 (m, —SO₂CH(CH₃)CH₂(CH₂)₈CH₃, 16H), 0.88 (t, —CH₂CH₂CH₃, 3H).

FeCP-C3(M) The synthetic procedure is similar to that of FeCP-C3. The final polymer product was a white waxy solid. The substitution rate was >95% based on the integration values of different protons. M_{n,SEC}=97.1 kDa and D=2.08. ¹H NMR (500 MHz, CDCl₃), δ (ppm)=3.76-3.52 (m, —CH₂CH(CH₂)O—, 3H), 3.49-3.26 (m, —SO₂CH₂CH(CH₃)CH₂SO₂CH(CH₃)CH₂—, 2H), 3.19 (t, —CH₂SO₂CH₂CH(CH₃)CH₂SO₂CH(CH₃)CH₂—, 2H), 3.11-3.01 (m, —CH₂SO₂CH₂CH(CH₃)CH₂SO₂CH(CH₃)CH₂—, 1H), 2.98-2.84 (m, —SO₂CH₂CH(CH₃)CH₂SO₂CH(CH₃)CH₂—, 3H), 2.83-2.59 (m, —CH₂SCH₂CH₂CH₂SO₂—, 4H), 2.18-2.05 (m, —SCH₂CH₂CH₂SO₂—, 2H), 2.04-1.92 (m, —SO₂CH₂CH(CH₃)CH₂SO₂CH(CH₃)CH₂—, 1H), 1.52-1.43 (m, —SO₂CH₂CH(CH₃)CH₂SO₂CH(CH₃)CH₂—, 1H), 1.42-1.39 (d, —SO₂CH₂CH(CH₃)CH₂SO₂CH(CH₃)CH₂—, 3H), 1.39-1.35 (m, —SO₂CH₂CH(CH₃)CH₂SO₂CH(CH₃)CH₂—, 3H), 1.34-1.17 (m, —SO₂CH(CH₃)CH₂(CH₂)₈CH₃, 16H), 0.88 (t, —CH₂CH₂CH₃, 3H).

### Results

### Self-Assembly in Disulfonylated Comb-Shaped Polymers

Phase transitions of FeCP-C3 and FeCP-C3(M) powder samples were studied by differential scanning calorimetry (DSC, see FIGS. 2B and C). For FeCP-C3 during the first cooling, two sharp exothermic peaks were seen at 203.4 and 112.0° C., with enthalpy changes of 6.2 and 32.9 J/g, respectively. During the second heating, a glass transition temperature (Tg) was found at 48° C., together with two endothermic peaks at 140.4° C. (33.6 J/g) and 207.7° C. (6.4 J/g). From the drastically different enthalpy changes and supercoolings of the two transitions during the cooling and heating cycle, the phase below 140.4° C. [i.e., the melting temperature (Tₘ)] should be a crystalline (K) phase, while the phase between 140.4 and 207.7° C. [i.e., the isotropization temperature (Tᵢ)] should be an LC phase. This assignment was further confirmed by polarized light microscopy (PLM) images of a powder sample (FIG. 2B). The K and LC structures were studied by temperature-dependent X-ray diffraction (XRD). From the fiber patterns of FeCP-C3 at 25° C. (FIG. 2D) and 160° C., lamellar reflections were seen on the equator in both K and LC phases with layer thicknesses being 4.6 and 4.4 nm, respectively. The inter-side chain scatterings on the meridian indicated an average distance of 0.45 nm and ~19° side chain tilting from the polymer main chain in the K phase. However, the average side-chain distance was 0.48 nm, and no side chain-tilting was seen in the LC phase this family of comb-shaped LCPs forms thermodynamically stable LC phases above the Tₘ of crystals, because their fiber and powder XRD signatures match. The powder XRD also matched the fiber XRD (FIG. 2D) for FeCP-C3, indicating that the LC phase was thermodynamically stable and not induced by mechanical stretching.

The observations of a single endothermic peak at 82.0° C. with a small enthalpy change of 4.2 J/g and birefringence at lower temperatures (FIG. 2C) reveal that FeCP-C3(M) had only an LC phase below Ti at 82.0° C., together with a Tg at 1.0° C. during heating. Similarly, FeCP-C3(M) also self-assembled into a layered structure of ~4.0 nm thick with no side chain-tilting below Ti (FIG. 2E). This fiber XRD matched the powder XRD, indicating an intrinsic layered LC structure. Given the side chain length, a double-layer structure is proposed for these two FE dipolar polymers (see FIG. 2F).

### Tunable Ferroelectricity

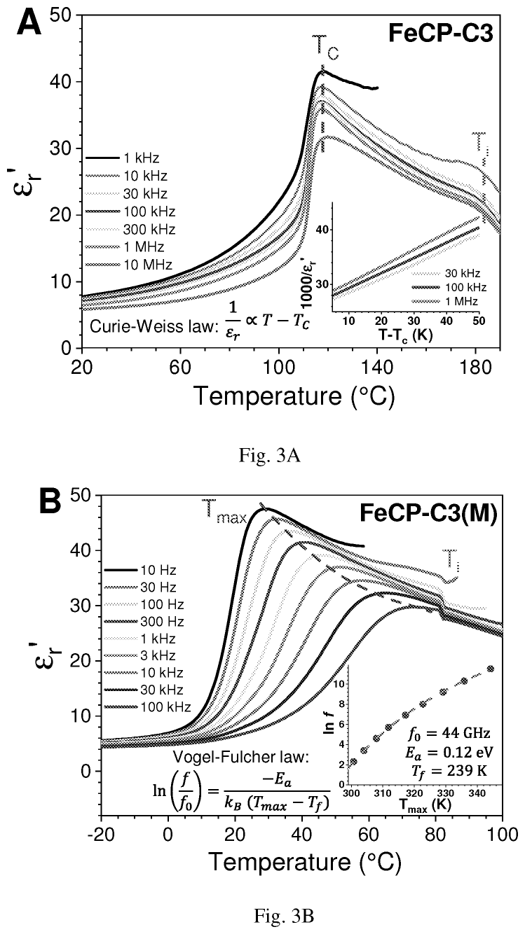

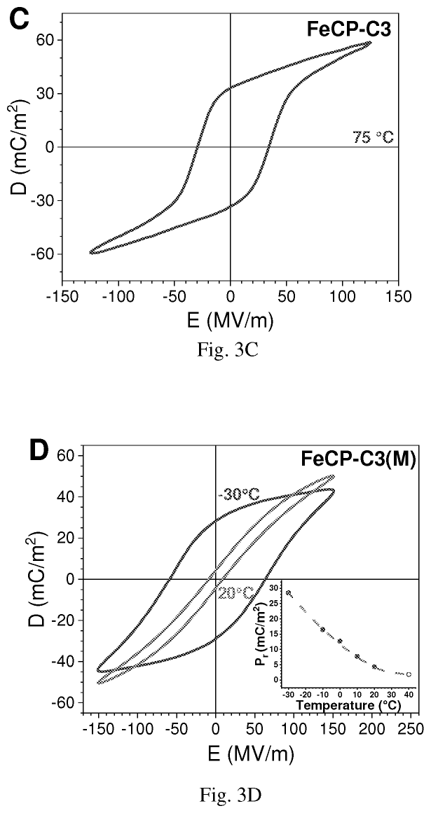

The ferroelectricity of these two dipolar polymers was examined using broadband dielectric spectroscopy (BDS) and electric displacement-electric field (D-E) loop tests. The real part of the relative permittivity (εr′) of FeCP-C3 (FIG. 3A) was measured in the temperature-scan BDS during cooling at 2° C./min. The peak in dielectric constant, which was independent of frequency at 118° C., coincided with the crystallization temperature (Tₓ) at 112° C. observed in the DSC cooling scan (FIG. 2B), indicating a FE-to-paraelectric (PE) Curie transition between the PE LC and the FE K phases in FeCP-C3. The 1/εᵣ′ vs. (T-T_{C}) exhibited a linear relationship for frequency between 30 kHz and 1 MHz (see the inset of FIG. 3A), fitting well to the Curie-Weiss law. Typical FE D-E hysteresis loops of FeCP-C3 were obtained at 75° C. (FIG. 3C). At a poling field of 125 MV/m, the remanent polarization (Pᵣ) was 33.2 mC/m², significantly higher than that (0.1-1 mC/m²) of typical FE SmC* LCPs. The coercive field was ~31 MV/m. From the plot of Pᵣ vs. poling field, the major Pᵣ was attributed to FE switching, rather than ionic conduction, when the poling field was above 75 MV/m.

Drastically different from FeCP-C3, FeCP-C3(M) exhibited a broad frequency-dependent εr′ peak in the temperature-scan BDS curves (FIG. 3B). A peak εᵣ′ as high as 48, comparable to those (50-60) of PVDF-based terpolymer relaxors, was found at 27.6° C. and 10 Hz. The temperature at the peak εr′ is denoted Tₘₐₓ. Both the high εr′ and the apparent frequency dependence of Tₘₐₓ suggest typical relaxor ferroelectricity in the FeCP-C3(M) near room temperature (RT). The frequency (f) dispersion is well described by the Vogel-Fulcher law: f=f₀exp[−Eₐ/(k_{B}(Tₘₐₓ−T_{f}))], where f₀ is the attempt frequency, Eₐ the activation energy, and T_{f} the freezing temperature. From the Vogel-Fulcher fitting, we obtain: T_{f}=239 K and Eₐ=0.12 eV (FIG. 3B inset). Unlike normal ferroelectrics with large domains, relaxors contain polar nanoregions or nanodomains with random orientations. Unfortunately, because the LC FeCP-C3(M) was very soft and should contain dynamic nanodomains at RT, piezoresponse force microscopy could not detect the nanodomains. Below T_{f}, relaxors can change to normal ferroelectrics due to enlarged and frozen nanodomains. Both slim RFE and broad FE D-E loops were observed for FeCP-C3(M) at 20° C. and −30° C., respectively (FIG. 3D). The Pᵣ decreased continuously from 28.5 mC/m² at −30° C. to 4.3 mC/m² at 20° C. (FIG. 3D and D-E).

### Molecular Dynamics Simulations

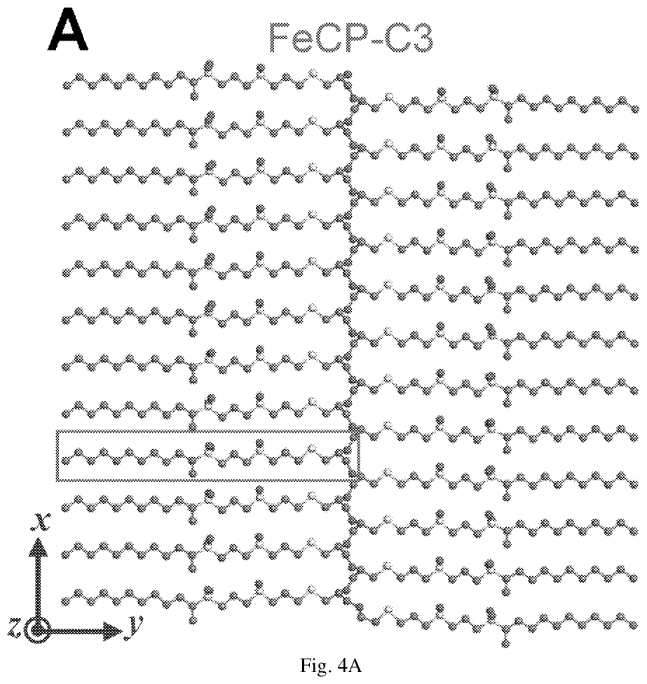

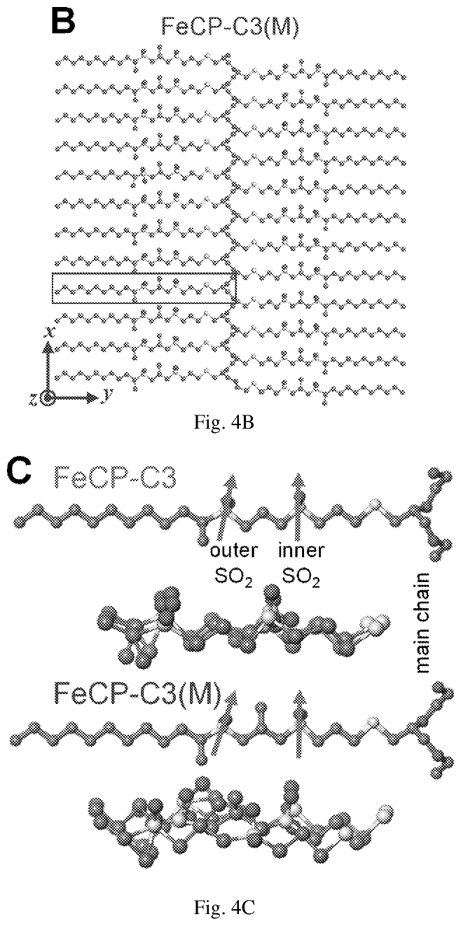

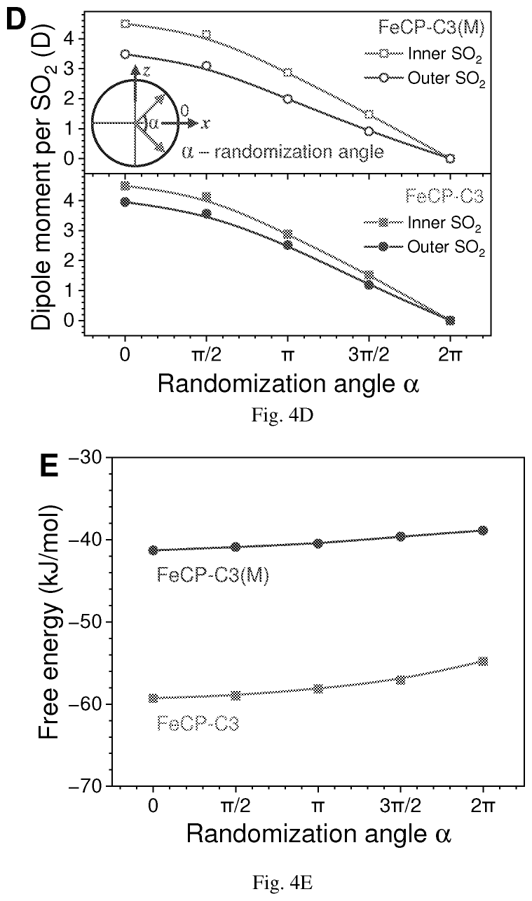

Because single crystals could not be obtained for these polymers and the atomic packing information remained unknown, molecular dynamics (MD) simulations were performed to investigate the mechanism of FE ordering. Simulated single-layer molecules of FeCP-C3 and FeCP-C3(M) are shown in FIG. 4A, respectively. Before MD simulation, the sulfonyl dipoles were initially randomized with an angle α, which is defined in the inset of FIG. 4D (α=π/2 for the molecules in FIG. 4, A to C). After MD simulation for each a, the average dipole moments of the inner and the outer sulfonyl groups were calculated. As a decreased from 2π to 0, the average dipole moments of inner and outer sulfonyl groups increased (FIG. 4D). The dipole moment of the inner sulfonyl groups was always higher than that of the outer sulfonyl groups. For example, when α=0, the average dipole moments of the inner sulfonyl groups for FeCP-C3 and FeCP-C3(M) were both 4.49 D, and those of the outer sulfonyl groups were 3.95 and 3.48 D, respectively. The average dipole moment of the outer sulfonyl group in FeCP-C3(M) was smaller than that in FeCP-C3. This can be visualized from the magnified side chains in FIG. 4C, where the inner sulfonyl groups were better aligned along the main chain than the outer sulfonyl groups, possibly due to the higher flexibility of the outer sulfonyl groups. We attribute the difference between FeCP-C3 and FeCP-C3(M) to the methyl branch in the C3 spacer of the disulfonyl group in FeCP-C3(M), whose steric hindrance prevents the parallel alignment of the two sulfonyl groups in one side chain. Finally, the free energies were calculated for FeCP-C3 and FeCP-C3(M) (FIG. 4E). FeCP-C3 had significantly lower free energy than FeCP-C3(M) at all α values. We conclude that the methyl branches in the C3 spacers destabilize FeCP-C3(M) as compared to FeCP-C3, which should explain why FeCP-C3 had much stronger polar ordering (i.e., FE) than FeCP-C3(M) (i.e., RFE).

### Example 2

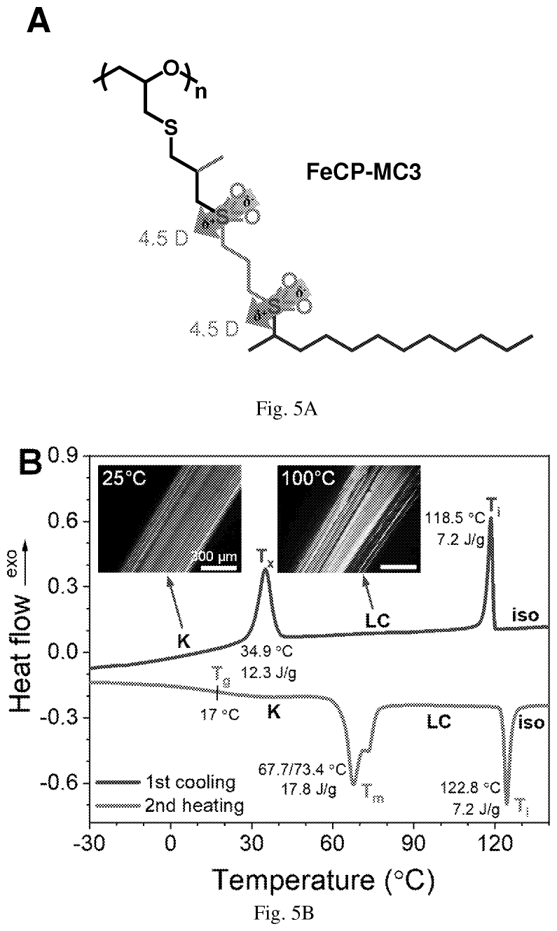

This Example describes the design of a disulfonylated side-chain polymer, FeCP-MC3 (FIG. 5A, FIG. 1C for synthesis), which can combine both ferroelectric (FE) (from crystals) and relaxor ferroelectric (RFE) behaviors (most likely from oriented amorphous fractions (OAFs)) within one sample, mimicking relaxor-based FE ceramic crystals. BDS results revealed that RFE and FE behavior coexisting in the sample, leading to high electrostriction: S₃=12.5% at 100 MV/m and |Q_{33,eff}| as high as 150-270 m⁴/C². The FE behavior originated from the FE crystals, and the RFE behavior should originate from the polar nanoregions (PNRs) in the OAF. Due to highly polarizable PNRs, high piezoelectricity was achieved: d₃₃~−680 pC/N, k₃₃~0.71, and η=0.51, which were comparable to that of PZT. FeCP-C3 and FeCP-C5, which include a polyoxypropylene main chain and disulfonyl alkyl side chains with a C3 and C5 spacer were also synthesized for comparison purposes.

### Methods

Instrumentation and Characterization Methods are described in Example 1.

### Synthesis Procedures

Synthesis procedures for FeCP-MC3 is shown in FIG. 1C. The syntheses of compound A3 is described in M.-H. Kwok et al., Achieving high permittivity paraelectric behavior in mesogen-free sulfonylated chiral polyethers with smectic C liquid crystalline self-assembly. Macromolecules 56, 1863-1874 (2023).

Compound B3. Compound A3 (5.0 g, 17.2 mmol), 1-chloro-3-bromo-2-methylpropane (8.5 g, 49.6 mmol), and K₂CO₃ (7.0 g, 50.7 mmol) were added into a 250 mL flask along with DMF (50 mL) as the solvent. After the reaction mixture was stirred under argon at room temperature(RT) for 12 h, it was poured into water (500 mL), and the product was extracted with hexane three times (200 mL×3). The organic phases were combined and washed with deionized water three times (200 mL×3) and then dried over anhydrous Na₂SO₄. After the evaporation of hexane via a rotary evaporator, the remaining liquid was dried in a vacuum oven at 40° C. for 3 days. The product was obtained as a colorless clear liquid (5.7 g, 90.9% yield) and used for the next step reaction without further purification. ¹H NMR (500 MHz, CDCl₃), δ (ppm)=3.66 (m, ClCH₂—, 2H), 2.81-2.45 (m, —SCH₂—, —SCH(CH₃)CH₂—, 7H), 2.10-2.01 (m, ClCH₂CH(CH₃)CH₂S—, 1H), 1.89-1.81 (m, —SCH₂CH₂CH₂S—, 2H), 1.59-1.49 (m, —SCH(CH₃)CH₂CH₂—, 1H), 1.48-1.41 (m, —SCH(CH₃)CH₂CH₂—, 1H), 1.33-1.18 (m, —SCH(CH₃)CH₂(CH₂)₈CH₃, 19H), 1.12-1.08 (dd, ClCH₂CH(CH₃)CH₂S—, 3H), 0.88 (t, —CH₂CH₃, 3H).

Compound C3. Compound B3 (5 g, 13.6 mmol) was dissolved with chloroform (100 mL) in a 500 mL flask and stirred in an ice-water bath for 30 min. Then, m-CPBA (20.5 g, ~70% purity, 83.2 mmol) was slowly added into the flask. The mixture was stirred at RT for 3 h. After chloroform was removed via a rotary evaporator, 1 M NaOH solution was used to wash away excess m-CPBA and the by-product, m-chlorobenzoic acid (m-CBA). The residue in the flask was dissolved in chloroform (100 mL) and transferred into a separatory funnel. The organic phase was washed with deionized water 3 times (200 mL×3) and dried over anhydrous Na₂SO₄. After the evaporation of chloroform via a rotary evaporator, the remaining liquid was dried in a vacuum oven at 40° C. overnight. The product was obtained as a colorless clear liquid (5.1 g, 87.2% yield) and used directly for the next step reaction without further purification. ¹H NMR (500 MHz, CDCl₃), δ (ppm)=3.80-3.74 (dd, ClCH₂—, 1H), 3.59-3.54 (dd, ClCH₂—, 1H), 3.34-3.25 (m, ClCH₂CH(CH₃)CH₂SO₂CH₂—, —SO₂CH₂CH₂CH₂SO₂CH(CH₃)CH₂—, 3H), 3.20-3.13 (m, —SO₂CH₂CH₂CH₂SO₂CH(CH₃)CH₂—, 2H), 2.97-2.86 (m, ClCH₂CH(CH₃)CH₂SO₂CH₂—, —SO₂CH₂CH₂CH₂SO₂CH(CH₃)CH₂—, 2H), 2.71-2.65 (m, ClCH₂CH(CH₃)CH₂SO₂CH₂—, 1H), 2.49-2.41 (m, —SO₂CH₂CH₂CH₂SO₂CH(CH₃)CH₂—, 2H), 2.05-1.93 (m, —SO₂CH₂CH₂CH₂SO₂CH(CH₃)CH₂—, 1H), 1.53-1.45 (m, —SO₂CH₂CH₂CH₂SO₂CH(CH₃)CH₂—, 1H), 1.38-1.36 (d, —SO₂CH₂CH₂CH₂SO₂CH(CH₃)CH₂—, 3H), 1.34-1.19 (m, ClCH₂CH(CH₃)CH₂SO₂CH₂—, —SO₂CH(CH₃)CH₂(CH₂)₈CH₃, 19H), 0.88 (t, —CH₂CH₂CH₃, 3H).

Compound D3. Compound C1 (5.0 g, 11.6 mmol) was dissolved by DMF (50 mL) in a 250 mL flask, and KSAc (2.0 g, 17.5 mmol) was added into the flask. The mixture was stirred at RT for 15 min with N₂ degassing. Then, the mixture was heated to 50° C. for 6 h with a gentle N₂ flow. After reaction, the mixture was poured into water (200 mL), extracted with chloroform for 3 times (100 mL×3). Then, the organic phase was combined and dried over anhydrous Na₂SO₄. After the evaporation of chloroform via a rotary evaporator, the remaining liquid was carefully purified by a silica gel column twice with a mixture of ethyl acetate and hexane as eluent (v:v=1:5). The purified product was a white solid (3.7 g, 72.3%). ¹H NMR (500 MHz, d₆-DMSO), δ (ppm)=3.29-3.08 (m, CH₃COSCH₂CH(CH₃)CH₂SO₂CH₂CH₂CH₂SO₂CH(CH₃)CH₂—, 8H), 2.92-2.86 (dd, CH₃COSCH₂CH(CH₃)CH₂SO₂—, 1H), 2.34 (s, CH₃COSCH₂—, 3H), 2.30-2.21 (m, CH₃COSCH₂CH(CH₃)CH₂SO₂—, 1H), 2.10-2.04 (m, —CH₂SO₂CH₂CH₂CH₂SO₂CH(CH₃)CH₂—, 2H), 1.87-1.78 (m, —CH₂CH₂CH₂SO₂CH(CH₃)CH₂—, 1H), 1.38-1.32 (m, —CH₂CH₂CH₂SO₂CH(CH₃)CH₂—, 1H), 1.31-1.19 (m, —CH₂CH₂CH₂SO₂CH(CH₃)CH₂(CH₂)₈CH₃, 19H), 1.10-1.15 (dd, CH₃COSCH₂CH(CH₃)CH₂SO₂—, 3H), 0.85 (t, —CH₂CH₂CH₃, 3H). ¹³C NMR (126 MHz, DMSO-d6), δ (ppm)=194.92, 79.18, 56.21, 56.15, 51.13, 46.77, 34.35, 31.30, 30.61, 28.99, 28.97, 28.82, 28.71, 28.68, 28.21, 28.06, 25.76, 22.11, 18.81, 14.70, 13.98, 12.41.

FeCP-MC3. NaH (135.0 mg, ~60 wt. % in paraffin oil, 3.4 mmol) was added into 50 mL anhydrous THF in a 250 mL three-neck flask equipped with a gas flow control adaptor and a condenser. Anhydrous ethanol (1.0 mL) was added dropwise into the flask at RT with stirring and the mixture was degassed with N₂ for 1 h. Then, compound D1 (2.0 g, 4.3 mmol) was slowly added into the flask with vigorous stirring at RT for 1 h. The flask was heated to 70° C., and PECH (190.0 mg, 2.0 mmol polymer repeating unit) was added into the flask. The reaction continued at 70° C. under the N₂ atmosphere for 48 h. After reaction, deionized water (200 mL) was added into the flask, and the precipitated crude polymer was collected. The crude polymer was dissolved in ~5 mL chloroform and precipitated in methanol (100 mL) five times for purification. The purified polymer was soaked in DI water (50 mL) at 40° C. for one week with daily change of DI water to minimize ion contamination. The final polymer was obtained as a white solid (759.3 mg, 76.3% yield). M_{n,SEC}=158.0 kDa and D=2.63, ¹H NMR (500 MHz, CDCl₃), δ (ppm)=3.76-3.53 (m, —CH₂CH(CH₂)O—, 3H), 3.38-3.11 (m, —SCH₂CH(CH₃)CH₂SO₂CH₂—, 1H), 3.26 (t, —SCH₂CH(CH₃)CH₂SO₂CH₂—, 2H), 3.22-3.11 (m, —SO₂CH₂CH₂CH₂SO₂CH(CH₃)CH₂—, 2H), 2.99-2.90 (m, —SCH₂CH(CH₃)CH₂SO₂CH₂—, —SO₂CH₂CH₂CH₂SO₂CH(CH₃)CH₂—, 2H), 2.83-2.75 (m, —CH₂SCH₂CH(CH₃)CH₂SO₂—, 1H), 2.73-2.59, (m, —CH₂SCH₂CH(CH₃)CH₂SO₂—, 3H), 2.48-2.31 (m, —CH₂SCH₂CH(CH₃)CH₂SO₂—, —SO₂CH₂CH₂CH₂SO₂CH(CH₃)CH₂—, 3H), 2.05-1.93 (m, —SO₂CH₂CH₂CH₂SO₂CH(CH₃)CH₂—, 1H), 1.53-1.45 (m, —SO₂CH₂CH₂CH₂SO₂CH(CH₃)CH₂—, 1H), 1.38-1.37 (d, —SO₂CH₂CH₂CH₂SO₂CH(CH₃)CH₂—, 3H), 1.34-1.19 (m, —CH₂SCH₂CH(CH₃)CH₂SO₂—, —SO₂CH(CH₃)CH₂(CH₂)₈CH₃, 19H), 0.88 (t, —CH₂CH₂CH₃, 3H).

### Results

FIG. 5B illustrates DSC curves for FeCP-MC3 at 10° C./min scanning rate. From the second heating differential scanning calorimetry (DSC) curve, FeCP-MC3 exhibited a crystalline [K, melting temperature (Tₘ) of 67.7/73.4° C. and heat of fusion ΔH_{f} of 17.8 J/g] and an LC phase before the isotropization temperature (Tᵢ, 122.8° C. with ΔH_{f}=7.2 J/g).

The inset two-dimensional (2D) X-ray diffraction (XRD) pattern of FeBP-MC3 at 25° C. showed clear lamellar reflections with a d-spacing of 4.83 nm. Upon cooling, Tᵢ and crystallization temperature (Tₓ) were seen at 118.5 and 34.9° C., respectively. FIG. 5C shows integrated 1D XRD curves of a melt-drawn FeCP-MC3 fiber at 25° C. and 100° C. The side chains are tilted at ~17° with respect to the normal direction of crystalline lamellae, based on the azimuthal scan result at q=13.6 nm⁻¹. The insets show corresponding 2D XRD patterns at 25° C. and 100° C.

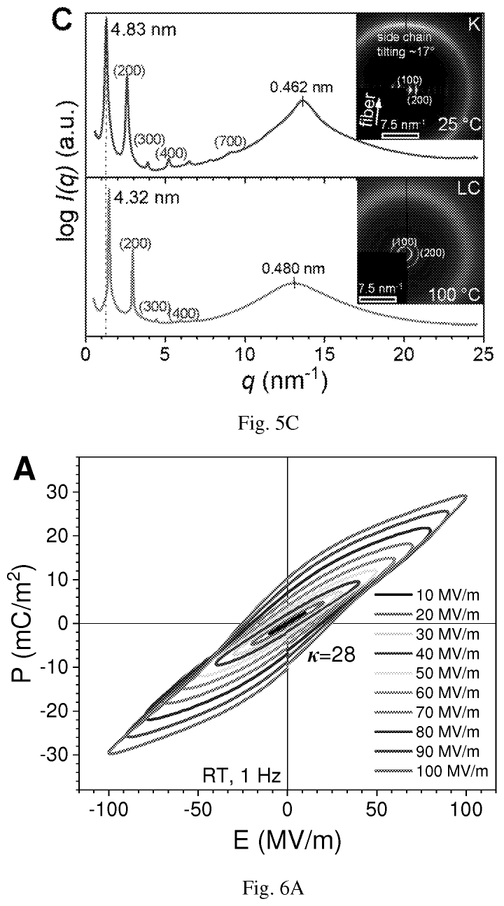

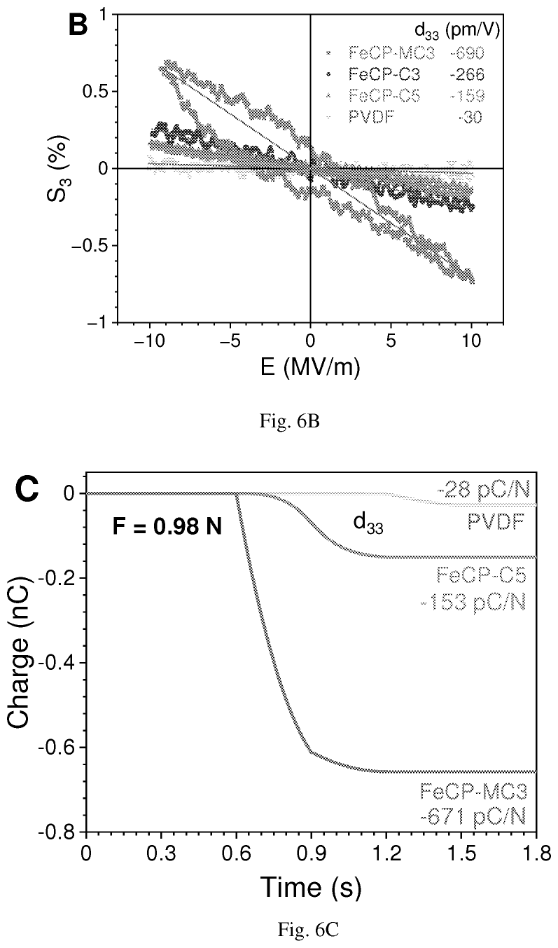

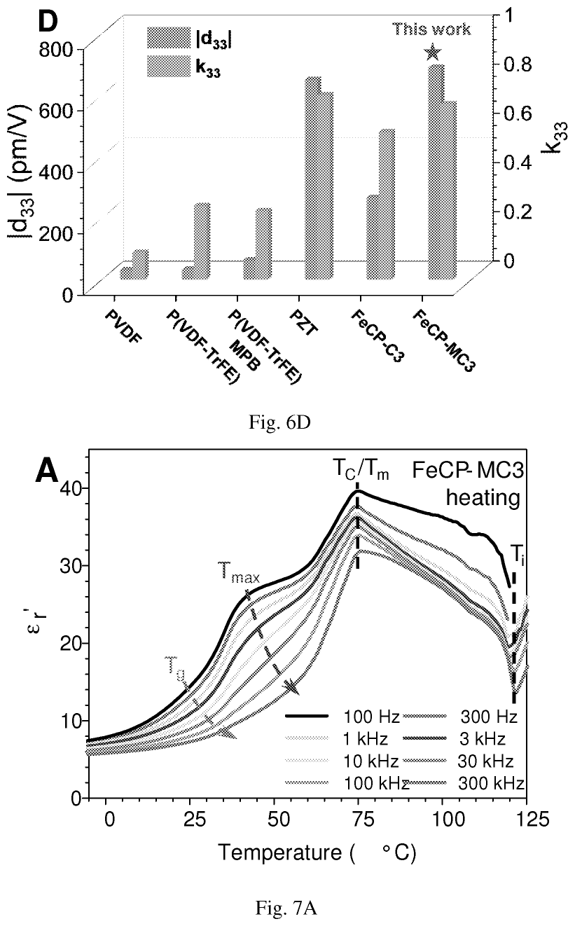

FIG. 6A illustrates P-E loops for electrically poled FeCP-MC3 at RT and 1 Hz. The electric poling was carried out at 100 MV/m (1 Hz) and 50° C. A typical FE polarization-electric field (P-E) loop was observed, where in-situ remanent polarization (Pᵣ) value was 26 mC/m² for FeCP-MC3.

FIG. 6B illustrates converse piezoelectric S₃-E loops (1 Hz) curves for FeCP-MC3, FeCP-C3, and FeCP-C5, respectively. From the converse piezoelectricity tests, giant piezoelectric strain constant d₃₃ values were obtained: −690 pm/V for FeCP-MC3, −266 pm/V for FeCP-C3, and −159 pm/V for FeCP-C5. These giant d₃₃ values were further confirmed by the direct d₃₃ measurements in FIG. 6C: −671 and −153 pC/N for FeCP-MC3 and FeCP-C5, respectively. Here, PVDF was used for comparison with a typical d₃₃ around −30 pC/N. The electromechanical coupling coefficient, k₃₃, could be obtained by: k₃₃=d₃₃[Y/(εᵣε₀)]^{0.5}, where Y is the Young's modulus, and εᵣ and ε₀ are relative permittivity and permittivity of vacuum, respectively. From frequency-scan broadband dielectric spectroscopy (BDS) and the P-E loop in FIG. 6A, Er was around 27 at 1 Hz for FeCP-MC3, 10 for FeCP-C3, and 14 for FeCP-C5. From dynamic mechanical analysis (DMA) results of FeCP-MC3 and FeCP-C5, Y at 1 Hz was determined: 269 MPa for FeBP-MC3, 450 MPa for FeCP-C3, and 358 MPa for FeBP-C5. Therefore, k₃₃ was determined: 0.71 for FeCP-MC3, 0.63 for FeCP-C3, and 0.26 for FeCP-C5 (FIG. 6D). As we can see, the |d₃₃| and k₃₃ values of FeCP-MC3 were comparable to those of PZT.

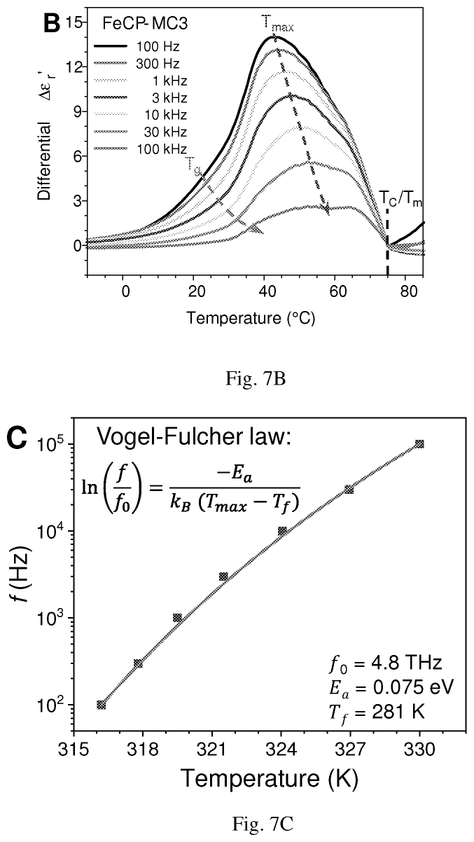

FIG. 7A shows the temperature-scan BDS results of the real part of relative permittivity (εᵣ′) for FeCP-MC3 under various frequencies (100 Hz to 300 kHz). Various transitions were observed with associated temperatures: a glass transition (T_{g}), a RFE transition (the maximum temperature Tₘₐₓ), a Curie transition (T_{C}, which coincides with the Tₘ), and finally a Tᵢ. To prove the Curie transition, Curie-Weiss law was used to fit the εᵣ′ curves around the T_{C}, and good fitting was obtained. To prove the RFE transition, a baseline BDS curve was constructed based on the εᵣ′ curves at 100 and 300 kHz. After normalization to the peak value at T_{C} and subtraction of this baseline BDS curve, the differential dielectric constant (Δεᵣ′) curves at different frequencies are shown in FIG. 6B. The Tₘₐₓ gradually shifted to higher frequencies and the peak intensity decreased. This behavior can be fitted with the Vogel-Fulcher equation, as shown in FIG. 6C. From the fitting, we obtained: reference frequency f₀=4.8 THz, activation energy Eₐ=0.075 eV, and the freezing temperature T_{f}=8° C., which was slightly lower than the T_{g} (17° C.).

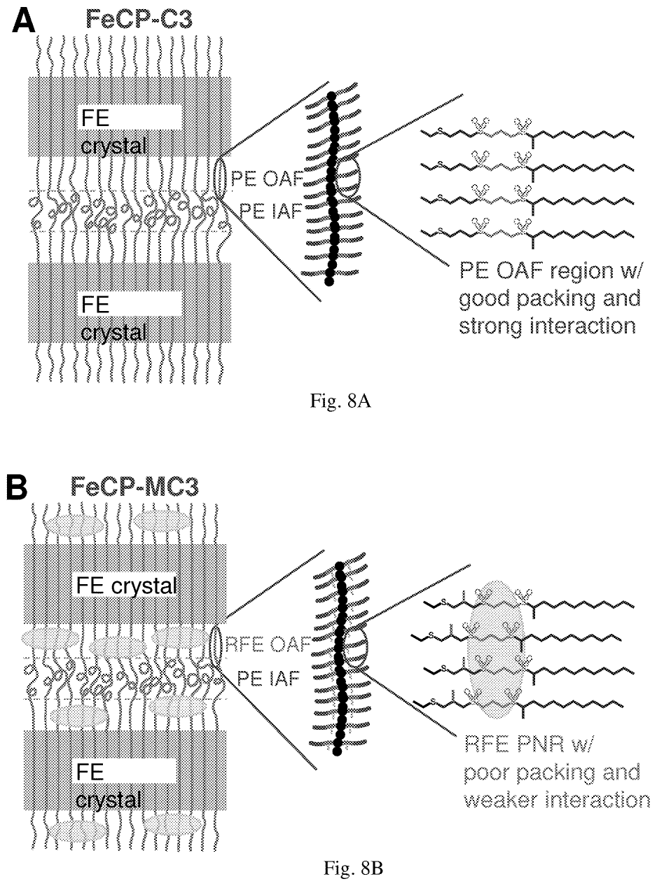

The coexistence of RFE and FE behaviors in FeCP-MC3 is reminiscent of the relaxor-based FE crystals. The highly polarizable PNRs contribute 50-80% of the ultrahigh piezoelectric properties (e.g., d₃₃>2000 pC/N) at RT, due to strong coupling between PNRs and the FE matrix. To explain the giant piezoelectricity of FeBP-MC3, we propose a molecular mechanism in FIG. 8B, taking advantage of the OAF concept for semicrystalline FE polymers. Supposedly, the IAF in FeBP-MC3 should be paraelectric (PE) because of their random orientation. The OAF chains stem out from the crystal basal planes and are more or less LC-like due to chain crowdedness. As discussed in Example 1, the LC FeCP-C3(M) exhibited RFE behavior with PNRs due to the disrupted/poor packing of doubly methylated side chains. We consider that the LC-like FeCP-MC3 chains in the OAF region should behave similarly and form PNRs. It is the strong coupling interactions between the neighboring FE crystals and PNRs in the OAF that cause giant electrostriction and piezoelectricity for the poled FeCP-MC3.

For comparison, due to lack of the second methyl side group, FeCP-C3 side chains described in Example 1 (FIG. 8A) have good packing with stronger dipole-dipole interactions, which could reduce dipole mobility and prevent their switchability. Therefore, the OAF in FeCP-C3 should be largely PE. Consequently, its dielectric and piezoelectric properties are worse than those of FeCP-MC3.

From the above description of the invention, those skilled in the art will perceive improvements, changes and modifications. Such improvements, changes and modifications within the skill of the art are intended to be covered by the appended claims. All references, publications, and patents cited in the present application are herein incorporated by reference in their entirety.

Having described the invention, we claim:

1. A fluorine-free ferroelectric polymer comprising a main chain and sulfonylated alkyl side chains, wherein each sulfonylated alkyl side chain includes at least one sulfonyl dipole, and wherein a sulfonyl group of each sulfonylated alkyl side chain is linked to the main chain with an at least 3 atoms in length aliphatic or heteroaliphatic linker.

2. The fluorine-free ferroelectric polymer of claim 1, wherein the polymer is mesogen-free and capable of forming layered crystalline or liquid crystalline structures.

3. The fluorine-free ferroelectric polymer of claim 1, having a comb-shaped structure wherein each repeating unit of the main polymer chain includes a sulfonylated alkyl side chain.

4. The fluorine-free ferroelectric polymer of claim 1, including nano- to micro-sized ferroelectric domains.

5. The fluorine-free ferroelectric polymer of claim 1, wherein the sulfonylated alkyl side chains have a dipole moment effective to induce strong dipolar interactions, polar/ferroelectric ordering of the polymer, and enhanced electroactive performance of the polymer.

6. The fluorine-free ferroelectric polymer of claim 1, exhibiting spontaneous polarization of at least 20 mC/m².

7. The fluorine-free ferroelectric polymer of claim 1, wherein each sulfonylated alkyl side chain is disulfonylated and includes an odd-numbered alkylene spacer between disulfonyl groups, which results in two substantially parallel sulfonyl dipoles.

8. The fluorine-free ferroelectric polymer of claim 7, wherein the alkylene spacer between disulfonyl groups of each disulfonylated alkyl side chain has the formula —SO₂—(CH₂)ₙ—SO₂—, where n is an odd number from 3 to 15.

9. The fluorine-free ferroelectric polymer of claim 7, wherein the alkylene spacer between disulfonyl groups of each disulfonylated alkyl side chain has the formula —SO₂CH₂CH(R)CH₂SO₂—, and where R is —H or a methyl group.

10. The fluorine-free ferroelectric polymer of claim 1, wherein each sulfonylated alkyl side chain includes an alkyl tail.

11. The fluorine-free ferroelectric polymer of claim 10, wherein the alkyl tail has formula —CH₂(R^{a})(CH₂)ₘCH₃, where R^{a} is —H or a methyl group and m is an integer from 1 to 16.

12. The fluorine-free ferroelectric polymer of claim 1, including one or more repeating units selected from: 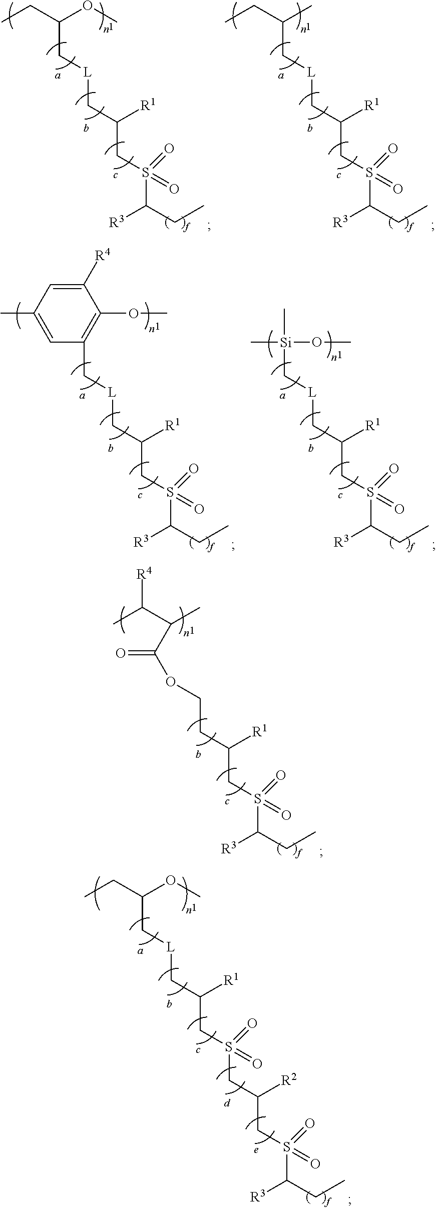 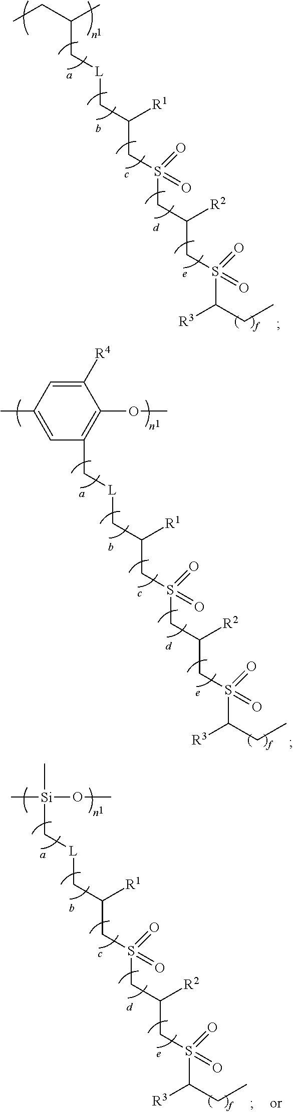 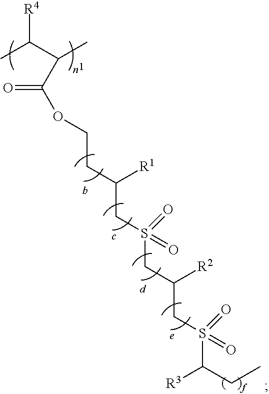
where
n¹ is an integer from 4 to 100;
a, b, c, d, e, and f are each independently an integer from 1 to 16;
L is —S—, —O—, or —CH₂—; and
R¹, R², R³, and R⁴ are each independently H or a methyl group.

13. The fluorine-free ferroelectric polymer of claim 12, wherein:
a, b, c, d, and e are each independently an integer from 1 to 3;
f is an integer from 1 to 10;
L is —S—, or —CH₂—; and
R¹, R², R³, and R⁴ are each independently H or methyl.

14. The fluorine-free ferroelectric polymer of claim 1 selected from: 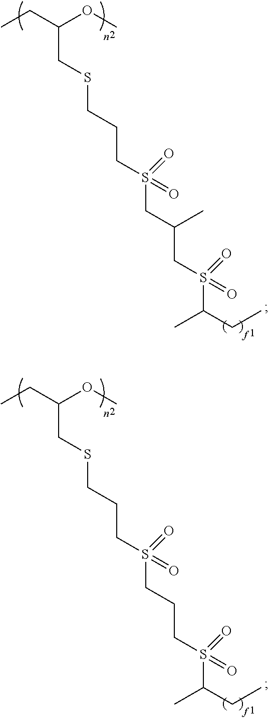 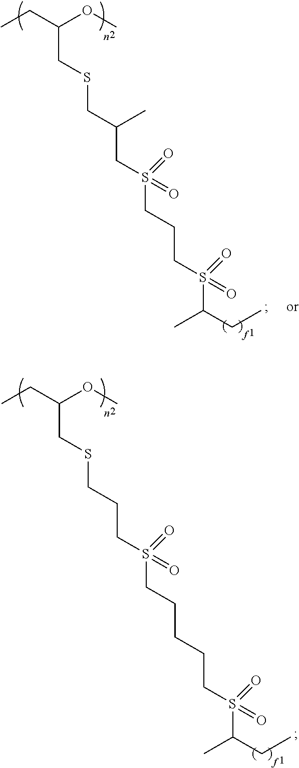
where n² is an integer from 4 to 100; and f² is an integer from 1 to 16.

15. The fluorine-free ferroelectric polymer of claim 1 selected from: 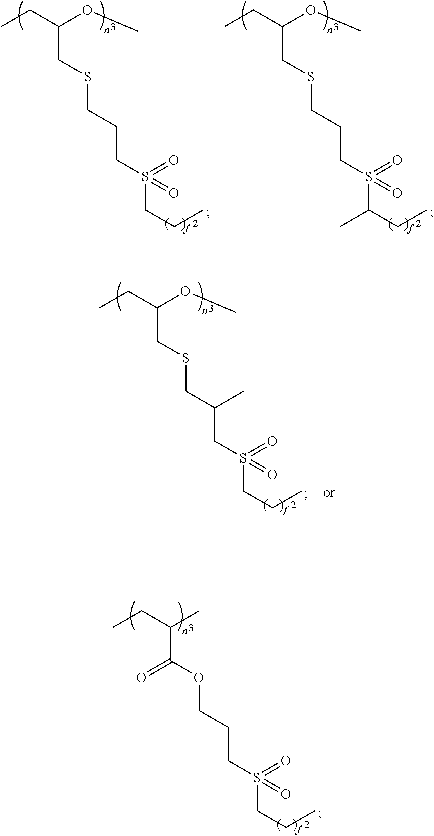
where n³ is an integer from 4 to 100; and f² is an integer from 1 to 16.

16. A piezoelectric material comprising the fluorine-free ferroelectric polymer of claim 1.

17. The piezoelectric material of claim 16, wherein the fluorine-free ferroelectric polymer has a piezoelectric coefficient |d₃₃| of at least about 150 pC/N at room temperature and an electromechanical coupling coefficient k₃₃ of at least about 0.25.

18. The piezoelectric material of claim 16, wherein the fluorine-free ferroelectric polymer has a piezoelectric coefficient |d₃₃| of at least about 260 pC/N at room temperature and an electromechanical coupling coefficient k₃₃ of at least about 0.6.

19. The piezoelectric material of claim 16, wherein the fluorine-free ferroelectric polymer has a piezoelectric coefficient |d₃₃| of at least about 670 pC/N at room temperature and an electromechanical coupling coefficient k₃₃ of at least about 0.7.

20. The piezoelectric material of claim 16, comprising at least a portion of a sensor, transducer, actuator, cooler, energy harvesting device, or energy storage device.
